(19) United States
(12) Patent Application Publication
(10) Pub. No.: US 2024/0224611 A1
(43) Pub. Date: Jul. 4, 2024

(54) DISPLAY DEVICE

(71) Applicant: LG Display Co., Ltd., Seoul (KR)

(72) Inventors: HangSup CHO, Paju-si (KR); YuHo JUNG, Paju-si (KR); Sungki HONG, Incheon (KR)

(21) Appl. No.: 18/507,850

(22) Filed: Nov. 13, 2023

(30) Foreign Application Priority Data
Dec. 30, 2022 (KR) 10-2022-0190608

(51) Int. Cl. H10K 59/122

(52) U.S. Cl. CPC H10K 59/122; G06F 3/0444

(57) ABSTRACT

A display device is provided. The display device according to an exemplary embodiment of the present specification includes a substrate including a non-display area and a display area which includes an optical area including a light-emitting area and a transmissive area, and a general area configured to surround the optical area, a planarization layer disposed on the substrate in the display area, a plurality of light-emitting elements disposed on the planarization layer and including an anode, a light-emitting layer, and a cathode, a bank disposed on the planarization layer and configured to cover an end of the anode, and a deposition-suppressing layer disposed on the light-emitting layer in the transmissive area among the light-emitting area and the transmissive area of the optical area, in which the bank is disposed in the light-emitting area among the light-emitting area and the transmissive area of the optical area.

### CROSS-REFERENCE TO RELATED APPLICATION

This application claims the priority of Korean Patent Application No.10-2022-0190608 filed on Dec. 30, 2022, in the Korean Intellectual Property Office, the disclosure of which is incorporated herein by reference.

### BACKGROUND

### Technical Field

The present specification relates to a display device.

### Description of the Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display (LCD) device, a field emission display (FED) device, an electrowetting display (EWD) device, an organic light-emitting display (OLED) device, and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

Recently, multimedia functions of mobile terminals have been improved. For example, a camera or sensor is basically embedded in a front surface of a display device. However, the camera or sensor disposed on the front surface of the display device restricts a screen design, which makes it difficult to implement the screen design. The display device adopts a design including a notch or punch hole to reduce a space occupied by the camera or sensor disposed on the front surface of the display device. However, a screen size is still restricted by the camera or sensor, which makes it difficult to implement a full-screen display.

To implement the full-screen display, there has been proposed a configuration in which an area, in which low-resolution pixels are disposed, is provided in a screen of a display device, and a camera and/or various types of sensors are disposed in the area in which the low-resolution pixels are disposed.

### BRIEF SUMMARY

The present disclosure provides a display device that has improved transmittance in an area in which a camera or sensor is disposed.

The present disclosure provides a display device capable of suppressing separation of a film stacked in an area in which a camera or sensor is disposed.

The present disclosure provides a display device capable of suppressing shrinkage of a pixel of a light-emitting part caused by outgassing of an organic material caused by transmission of UV rays during a process of evaluating UV reliability in an area in which a camera or sensor is disposed.

Technical features of the present disclosure are not limited to those above-mentioned, and other technical features and benefits, which are not mentioned above, can be clearly understood by those skilled in the art from the following descriptions.

According to an aspect of the present disclosure, a display device includes: a substrate including a non-display area and a display area which includes an optical area including a light-emitting area and a transmissive area, and a general area adjacent to the optical area; a planarization layer disposed on the substrate in the display area; a plurality of light-emitting elements disposed on the planarization layer and including an anode, a light-emitting layer, and a cathode; a bank disposed on the planarization layer and configured to cover an end of the anode; and a deposition-suppressing layer disposed on the light-emitting layer in the transmissive area among the light-emitting area and the transmissive area of the optical area, in which the bank is disposed in the light-emitting area among the light-emitting area and the transmissive area of the optical area.

According to another aspect of the present disclosure, a display device includes: a substrate comprising a non-display area and a display area which includes an optical area including a light-emitting area and a transmissive area, and a general area configured to adjacent to the optical area; a planarization layer disposed on the substrate in the display area; a plurality of light-emitting elements disposed on the planarization layer and including an anode, a light-emitting layer and a cathode; a deposition-suppressing layer disposed on the light-emitting layer in the transmissive area, wherein the deposition-suppressing layer does not overlap the cathode; and an optical-electronic device disposed on a lower portion of the substrate in the optical area, wherein the optical-electronic device overlaps the deposition-suppressing layer.

Other detailed matters of the exemplary embodiments are included in the detailed description and the drawings.

According to the display device according to the exemplary embodiment of the present specification, the camera or sensor is disposed at the lower end of the light-emitting element or the touch electrode in the display area, such that the display or touch at the upper side thereof may not be disconnected.

According to the display device according to the exemplary embodiment of the present specification, the deposition-suppressing layer is disposed in the area that overlaps the area in which the camera or sensor is disposed. Thereafter, the metal electrode is deposited. Therefore, the transmissive area, in which an opaque constituent element such as a metal electrode is not disposed, may be positioned on the deposition-suppressing layer. Therefore, the light transmittance of the area in which the camera or sensor is disposed may be improved, thereby improving the visual sensitivity of the display device.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIGS. 1A to 1D are schematic top plan views of a display device according to an exemplary embodiment of the present specification;

FIG. 2 is a system configuration view of the display device according to the exemplary embodiment of the present specification;

FIG. 3 is an equivalent circuit diagram of a subpixel of the display panel according to the exemplary embodiment of the present specification;

FIG. 4 is a view illustrating an arrangement of subpixels in a display area of a display panel according to the exemplary embodiment of the present specification;

FIG. 5A is a view illustrating an example of an arrangement of signal lines in a first optical area and a general area of the display panel according to the exemplary embodiment of the present specification;

FIG. 5B is a view illustrating an example of an arrangement of signal lines in a second optical area and the general area of the display panel according to the exemplary embodiment of the present specification;

FIG. 6 is a cross-sectional view illustrating a cross-sectional structure of one pixel area disposed in the general area according to the exemplary embodiment of the present specification;

FIG. 7 is a cross-sectional view illustrating cross-sectional structures of a light-emitting area and a transmissive area in an optical area according to the exemplary embodiment of the present specification;

FIG. 8A is a view illustrating a positional relationship between the transmissive area and a deposition-suppressing layer according to the exemplary embodiment of the present specification;

FIG. 8B is an enlarged view of the transmissive area according to the exemplary embodiment of the present specification;

FIG. 9 is a cross-sectional view illustrating cross-sectional structures of a light-emitting area and a transmissive area in an optical area according to another exemplary embodiment of the present specification;

FIG. 10A is a view illustrating a positional relationship between the transmissive area and a deposition-suppressing layer according to another exemplary embodiment of the present specification;

FIG. 10B is an enlarged view of the transmissive area according to another exemplary embodiment of the present specification;

FIG. 11 is a top plan view illustrating a first optical area of a flexible display device according to another exemplary embodiment of the present specification; and

FIG. 12 is an enlarged view illustrating area Z in FIG. 11.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

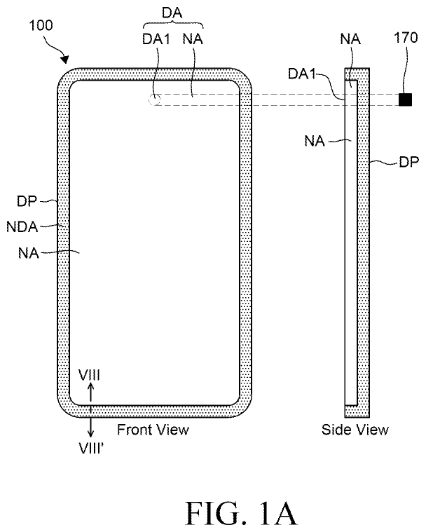

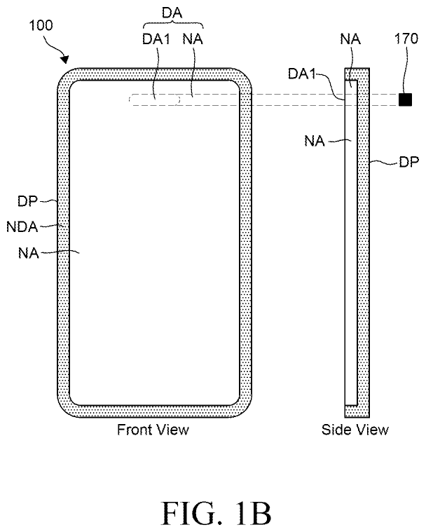

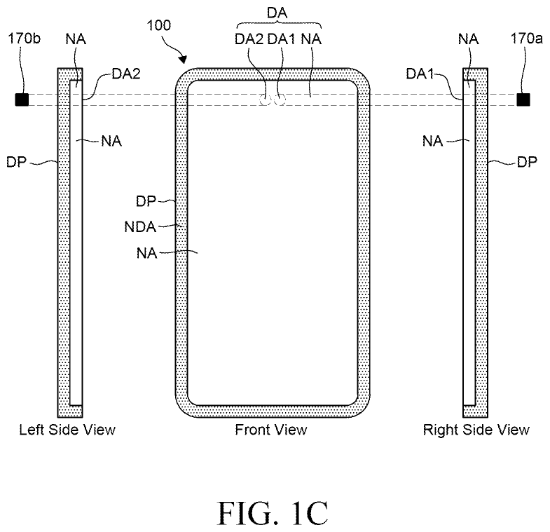

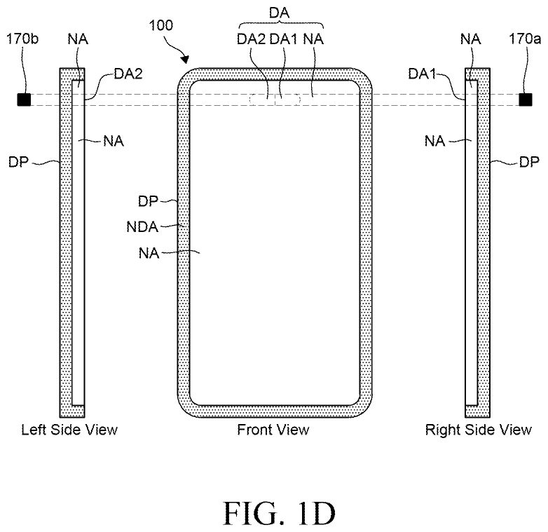

FIGS. 1A to 1D are schematic top plan views of a display device according to an exemplary embodiment of the present specification.

With reference to FIGS. 1A to 1D, a display device 100 according to an exemplary embodiment of the present specification may include a display panel DP configured to display images, and one or more optical-electronic devices 170, 170a, and 170b. The optical-electronic devices 170, 170a, and 170b may each include a light-receiving device, such as a camera or sensor, that receives light.

The display panel DP is a panel configured to display images to a user.

The display panel DP may include a display element configured to display images, a driving element configured to operate the display element, and lines configured to transmit various types of signals to the display element and the driving element. Different display elements may be defined depending on the types of display panels DP. For example, in a case in which the display panel DP is an organic light-emitting display panel, the display element may be an organic light-emitting element including an anode, a light-emitting layer, and a cathode. For example, in a case in which the display panel DP is a liquid crystal display panel, the display element may be a liquid crystal display element.

Hereinafter, it is assumed that the display panel DP is the organic light-emitting display panel. However, the display panel DP is not limited to the organic light-emitting display panel.

Meanwhile, the display panel DP may include a substrate, and a plurality of insulation films, transistor layers, and light-emitting element layers disposed on the substrate. To display images, the display panel DP may include a plurality of subpixels, and various types of signal lines configured to operate the plurality of subpixels. The signal lines may include a plurality of data lines, a plurality of gate lines, a plurality of power lines, and the like. In this case, the plurality of subpixels may each include a transistor positioned on a transistor layer, and a light-emitting element positioned on a light-emitting element layer.

The display panel DP may include a display area DA and a non-display area NDA.

The display area DA is an area of the display panel DP in which images are displayed.

The display area DA may include the plurality of subpixels constituting a plurality of pixels, and a circuit configured to operate the plurality of subpixels. The plurality of subpixels is minimum units constituting the display area DA. The display element may be disposed in each of the plurality of subpixels. The plurality of subpixels may constitute the pixel. For example, the plurality of subpixels may each include an organic light-emitting element including an anode, a light-emitting layer, and a cathode. However, the present disclosure is not limited thereto. In addition, the circuit configured to operate the plurality of subpixels may include driving elements, lines, and the like. For example, the circuit may include a thin-film transistor, a storage capacitor, a gate line, a data line, and the like. However, the present disclosure is not limited thereto.

The non-display area NDA is an area in which no image is displayed.

The non-display area NDA may be bent, such that the non-display area NDA is not visible from a front surface. The non-display area NDA may be covered by a casing (not illustrated). The non-display area NDA is called a bezel area.

FIGS. 1A to 1D illustrate that the non-display area NDA is adjacent to the display area DA having a quadrangular shape. However, the shapes and arrangements of the display area DA and the non-display area NDA are not limited to the example illustrated in FIGS. 1A to 1D. That is, the display area DA and the non-display area NDA may be suitable for the design of an electronic device equipped with the flexible display device 100. For example, an exemplary shape of the display area DA may also be a pentagonal shape, a hexagonal shape, a circular shape, an elliptical shape, or the like.

Various lines and circuits for operating the organic light-emitting element in the display area DA may be disposed in the non-display area NDA. For example, the non-display area NDA may include link lines for transmitting signals to the plurality of subpixels and the circuit in the display area DA. The non-display area NDA may include gate-in-panel (GIP) lines or drive ICs such as gate driver ICs and data driver ICs. However, the present disclosure is not limited thereto.

The display device 100 may further include various additional elements configured to generate various signals or operate the pixel in the display area DA. The additional elements for operating the pixel may include an inverter circuit, a multiplexer, an electrostatic discharge (ESD) circuit, and the like. The display device 100 may also include additional elements related to functions other than the function of operating the pixel. For example, the display device 100 may further include additional elements that provide a touch detection function, a user certification function (e.g., fingerprint recognition), a multi-level pressure detection function, a tactile feedback function, and the like. The above-mentioned additional elements may be positioned in the non-display area NDA and/or an external circuit connected to a connection interface.

With reference to FIGS. 1A to 1D, the display area DA may include a first optical area DA1 and a second optical area DA2. However, the present disclosure is not limited thereto.

In FIGS. 1A to 1D, the one or more optical-electronic devices 170, 170a, and 170b are electronic components positioned at a lower side (a side opposite to a visual surface) of the display panel DP.

The light may enter the front surface (visual surface) of the display panel DP. passes through the display panel DP, and then propagate to the one or more optical-electronic devices 170, 170a, and 170b positioned at the lower side (the side opposite to the visual surface) of the display panel DP.

The one or more optical-electronic devices 170, 170a, and 170b may be devices that receive the light having passed through the display panel DP and perform predetermined functions in response to the received light.

For example, the optical-electronic devices 170, 170a, and 170b may each include one of or both a camera and a proximity sensor.

As described above, the optical-electronic devices 170, 170a, and 170b may be devices that need to receive the light. However, the optical-electronic devices 170, 170a, and 170b may be positioned at the lower side of the display panel DP. That is, the optical-electronic devices 170, 170a, and 170b may be positioned at the side opposite to the visual surface of the display panel DP. The optical-electronic devices 170, 170a, and 170b are not exposed to the front surface of the flexible display device 100. Therefore, the user does not visually recognize the optical-electronic devices 170, 170a, and 170b when the user looks at the front surface of the flexible display device 100.

For example, the camera positioned at the lower side of the display panel DP may be a front surface camera configured to capture an image of an object disposed forward of the camera. The camera may be a camera lens.

The optical-electronic devices 170, 170a, and 170b may be disposed to overlap the display area DA of the display panel DP. That is, the optical-electronic devices 170, 170a, and 170b may be positioned in the display area DA.

With reference to FIGS. 1A to 1D, the display area DA may include a general area NA and the one or more optical areas DA1 and DA2.

The one or more optical areas DA1 and DA2 may be areas that overlap the one or more optical-electronic devices 170, 170a, and 170b.

According to the example in FIG. 1A, the display area DA may include the general area NA and the first optical area DA1. In this case, at least a part of the first optical area DA1 may overlap a first optical-electronic device 170.

FIG. 1A illustrates that the first optical area DA1 has a circular structure. However, the shape of the first optical area DA1 according to the exemplary embodiment of the present specification is not limited thereto.

For example, as illustrated in FIG. 1B, the shape of the first optical area DA1 may be an octagonal shape or various polygonal shapes.

According to the example in FIG. 1C, the display area DA may include the general area NA, the first optical area DA1, and the second optical area DA2. In the example in FIG. 1C, the general area NA may be present between the first optical area DA1 and the second optical area DA2. In this case, at least a part of the first optical area DA1 may overlap the first optical-electronic device 170a, and at least a part of the second optical area DA2 may overlap a second optical-electronic device 170b.

According to the example in FIG. 1D, the display area DA may include the general area NA, the first optical area DA1, and the second optical area DA2. In the example in FIG. 1D. the general area NA is not present between the first optical area DA1 and the second optical area DA2. That is, the first optical area DA1 and the second optical area DA2 may adjoin each other. In this case, at least a part of the first optical area DA1 may overlap the first optical-electronic device 170a, and at least a part of the second optical area DA2 may overlap the second optical-electronic device 170b.

The one or more optical areas DA1 and DA2 each need to have both an image display structure and a light transmission structure. That is, because the one or more optical areas DA1 and DA2 are partial areas of the display area DA, the subpixels for displaying images need to be disposed in the one or more optical areas DA1 and DA2. The one or more optical areas DA1 and DA2 each need to have the light transmission structure for transmitting light to the one or more optical-electronic devices 170, 170a, and 170b.

The one or more optical-electronic devices 170, 170a, and 170b are devices that need to receive light. However, the one or more optical-electronic devices 170, 170a, and 170b are positioned at a rear side (the lower side, i.e., the side opposite to the visual surface) of the display panel DP and receive the light having passed through the display panel DP.

The one or more optical-electronic devices 170, 170a, and 170b are not exposed to the front surface (visual surface) of the display panel DP. Therefore, the user does not visually recognize the optical-electronic devices 170, 170a, and 170b when the user looks at the front surface of the flexible display device 100.

For example, the first optical-electronic device 170 (170a) may be a camera, and the second optical-electronic device 170b may be a detection sensor such as a proximity sensor or an illuminance sensor. For example, the detection sensor may be an infrared sensor that detects infrared rays.

On the contrary, the first optical-electronic device 170 (170a) may be a detection sensor, and the second optical-electronic device 170b may be a camera.

Hereinafter, for convenience of description, an example will be described in which the first optical-electronic device 170 (170a) is a camera, and the second optical-electronic device 170b is a detection sensor. In this case, the camera may be a camera lens or an image sensor.

In case that the first optical-electronic device 170 (170a) is a camera, the camera may be positioned at the rear side (lower side) of the display panel DP. However, the camera may be the front surface camera configured to capture an image of an object disposed forward of the display panel DP. Therefore, the user may capture an image by using the camera, which is not visible from the visual surface, while looking at the visual surface of the display panel DP.

The general area NA and the one or more optical areas DA1 and DA2, which are included in the display area DA, are areas in which images may be displayed. However, the general area NA is an area that does not require the light transmission structure, and the one or more optical areas DA1 and DA2 are areas that need to have the light transmission structures.

Therefore, the one or more optical areas DA1 and DA2 each need to have transmittance at a predetermined level or higher. The general area NA may not have optical transmittance or have low transmittance at less than the predetermined level.

For example, the one or more optical areas DA1 and DA2 and the general area NA may be different in resolution, subpixel arrangement structure, number of subpixels per unit area, electrode structure, line structure, electrode arrangement structure, line arrangement structure, or the like.

For example, the number of subpixels per unit area in each of the one or more optical areas DA1 and DA2 may be smaller than the number of subpixels per unit area in the general area NA. That is, the resolution in each of the one or more optical areas DA1 and DA2 may be lower than the resolution in the general area NA. In this case, the number of subpixels per unit area may be a criterion for measuring the resolution and may also be referred to as PPI (pixels per inch) that means the number of pixels within 1 inch.

For example, the number of subpixels per unit area in the first optical area DA1 may be smaller than the number of subpixels per unit area in the general area NA. The number of subpixels per unit area in the second optical area DA2 may be equal to or larger than the number of subpixels per unit area in the first optical area DA1.

The first optical area DA1 may have various shapes such as a circular shape, an elliptical shape, a quadrangular shape, a hexagonal shape, or an octagonal shape. The second optical area DA2 may have various shapes such as a circular shape, an elliptical shape, a quadrangular shape, a hexagonal shape, or an octagonal shape. The first optical area DA1 and the second optical area DA2 may have the same shape or different shapes.

With reference to FIG. 1C, in case that the first optical area DA1 and the second optical area DA2 adjoin each other, an overall optical area including the first optical area DA1 and the second optical area DA2 may have various shapes such as a circular shape, an elliptical shape, a quadrangular shape, a hexagonal shape, or an octagonal shape.

Hereinafter, for convenience of description, an example will be described in which the first optical area DA1 and the second optical area DA2 each have a circular shape.

In the flexible display device 100 according to the exemplary embodiment of the present specification, in case that the first optical-electronic device 170 (170a), which is hidden at the lower side of the display panel DP without being exposed to the outside, is a camera, the flexible display device 100 according to the exemplary embodiment of the present specification may be a display to which an under-display camera (UDC) technology is applied.

According to this configuration, in the flexible display device 100 according to the exemplary embodiment of the present specification, a notch or camera hole for exposing a camera need not be formed in the display panel DP, such that an area of the display area DA does not decrease.

Therefore, because the notch or camera hole for exposing the camera need not be formed in the display panel DP, a size of a bezel area may decrease, and a design constraint may be eliminated, such that a degree of freedom may increase.

In the flexible display device 100 according to the exemplary embodiment of the present specification, even though the one or more optical-electronic devices 170, 170a, and 170b are positioned to be hidden at the rear side of the display panel DP, the one or more optical-electronic devices 170, 170a, and 170b need to normally receive light and normally perform the predetermined functions.

In addition, in the flexible display device 100 according to the exemplary embodiment of the present specification, even though the one or more optical-electronic devices 170, 170a, and 170b are positioned to be hidden at the rear side of the display panel DP and positioned to overlap the display area DA, images need to be normally displayed in the one or more optical areas DA1 and DA2 that overlap the one or more optical-electronic devices 170, 170a, and 170b in the display area DA.

Therefore, the flexible display device 100 according to the exemplary embodiment of the present specification may have a structure capable of improving the transmittance of the first optical area DA1 and the second optical area DA2 that overlap the optical-electronic devices 170, 170a, and 170b.

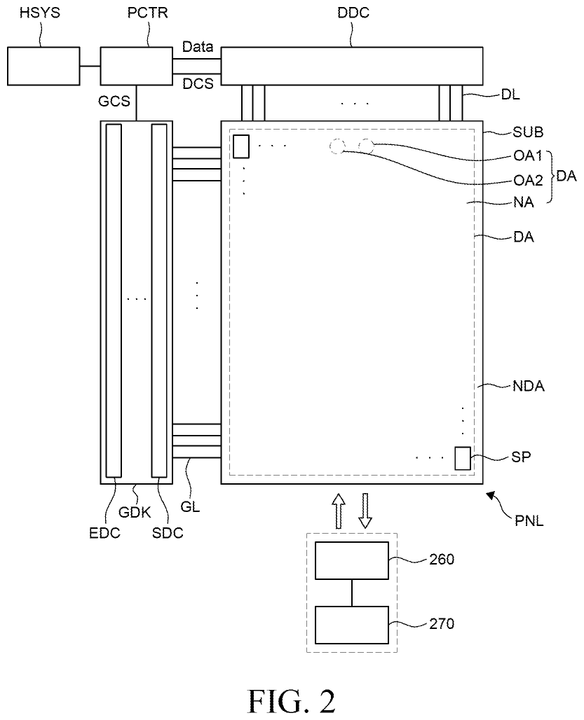

FIG. 2 is a system configuration view of the display device according to the exemplary embodiment of the present specification.

With reference to FIG. 2, the display device 100 may include the display panel DP and a display drive circuit that are constituent elements for displaying images.

The display drive circuit may be a circuit for operating the display panel DP and include a data drive circuit DDC, a gate drive circuit GDC, and a display controller DCTR.

The display panel DP may include the display area DA in which images are displayed, and the non-display area NDA in which no image is displayed. The non-display area NDA may be an outer peripheral area of the display area DA and also referred to as a bezel area. The entirety or a part of the non-display area NDA may be an area visible from the front surface of the display device 100 or an area that is bent and not visible from the front surface of the display device 100.

The display panel DP may include a substrate SUB, and a plurality of subpixels SP disposed on the substrate SUB. In addition, the display panel DP may further include various types of signal lines to operate the plurality of subpixels SP.

The display device 100 according to the exemplary embodiments of the present specification may be a liquid crystal display device or an autonomous light-emitting display device having the display panel DP that autonomously emits light. In case that the display device 100 according to the exemplary embodiments of the present specification is an autonomous light-emitting display device, the plurality of subpixels SP may each include a light-emitting element.

For example, the display device 100 according to the exemplary embodiments of the present specification may be an organic light-emitting display device in which a light-emitting element is implemented as an organic light-emitting diode (OLED). As another example, the display device 100 according to the exemplary embodiments of the present specification may be an inorganic light-emitting display device in which a light-emitting element is implemented as a light-emitting diode made of an inorganic material. As still another example, the display device 100 according to the exemplary embodiments of the present specification may be a quantum dot display device implemented by quantum dots, which are semiconductor crystals, so that a light-emitting element autonomously emits light.

The structure of each of the plurality of subpixels SP may vary depending on the type of display device 100. For example, in case that the display device 100 is an autonomous light-emitting display device having the subpixel SP that autonomously emits light, the subpixels SP may each include a light-emitting element configured to autonomously emit light, one or more transistors, and one or more capacitors.

For example, various types of signal lines may include a plurality of data lines DL configured to transmit data signals (also referred to as data voltages or image signals), and a plurality of gate lines GL configured to transmit gate signals (also referred to as scan signals).

The plurality of data lines DL and the plurality of gate lines GL may intersect one another. The plurality of data lines DL may each be disposed while extending in a first direction. The plurality of gate lines GL may each be disposed while extending in a second direction.

In this case, the first direction may be a column direction, and the second direction may be a row direction. Alternatively, the first direction may be a row direction, and the second direction may be a column direction.

The data drive circuit DDC may be a circuit for operating the plurality of data lines DL and output data signals to the plurality of data lines DL. The gate drive circuit GDC may be a circuit for operating the plurality of gate lines GL and output gate signals to the plurality of gate lines GL.

The display controller DCTR may be a device for controlling the data drive circuit DDC and the gate drive circuit GDC and control driving timing for the plurality of data lines DL and driving timing for the plurality of gate lines GL.

The display controller DCTR may supply a data drive control signal DCS to the data drive circuit DDC to control in order to control the data drive circuit DDC and supply a gate drive control signal GCS to the gate drive circuit GDC in order to control the gate drive circuit GDC.

The display controller DCTR may receive input image data from a host system HSYS and supply image data Data to the data drive circuit DDC on the basis of the input image data.

The data drive circuit DDC may supply the data signals to the plurality of data lines DL on the basis of driving timing control of the display controller DCTR.

The data drive circuit DDC may receive digital image data Data from the display controller DCTR, convert the received image data Data into analog data signals, and output the analog data signals to the plurality of data lines DL.

The gate drive circuit GDC may supply the gate signals to the plurality of gate lines GL on the basis of timing control of the display controller DCTR. The gate drive circuit GDC may generate gate signals by receiving a first gate voltage, which corresponds to a turn-on level voltage, and a second gate voltage, which corresponds to a turn-off level voltage, together with various types of gate driving control signals GCS and supply the generated gate signals to the plurality of gate lines GL.

The gate drive circuit GDC supplies the gate signal to the gate line GL in response to the gate drive control signal GCS supplied from the display controller DCTR. The gate drive circuit GDC may be disposed at one side or two opposite sides of the display panel 100 in a gate-in-panel (GIP) manner.

The gate drive circuit GDC sequentially outputs the gate signals to the plurality of gate lines GL under the control of the display controller DCTR. The gate drive circuit GDC may shift the gate signals by using a shift register and sequentially supply the signals to the gate lines GL.

In the organic light-emitting display device, the gate signals may include a scan signal SC and a light-emitting control signal EM. The scan signal SC includes a scan signal pulse that swings between the first gate voltage and the second gate voltage. The light-emitting control signal EM may include a light-emitting control signal pulse that swings between a third gate voltage and a fourth gate voltage.

The scan pulse is synchronized with a data voltage Vdata and selects the subpixels SP on the line to which data is written. The light-emitting control signal EM defines light-emitting time of each of the subpixels SP.

The gate drive circuit GDC may include a light-emitting control signal drive part EDC configured to output the light-emitting control signal EM, and one or more scan drive parts SDC configured to output the scan signal SC.

The light-emitting control signal drive part EDC outputs the light-emitting control signal EM in response to a start pulse and a shift clock from the display controller DCTR and sequentially shifts the light-emitting control signal pulse in response to the shift clock.

The one or more scan drive parts SDC output the scan signal SC in response to the start pulse and the shift clock from the display controller DCTR and shift the scan signal pulse in accordance with a shift clock timing.

In the gate drive circuit GDC disposed in the GIP manner, the shift registers may be configured symmetrically at two opposite sides of the display area DA. In addition, the gate drive circuit GDC may be configured such that the shift register at one side of the display area DA includes at least one scan drive part SDC and a light-emitting control signal drive part EDC, and the shift register at the other side of the display area DA includes at least one scan drive part SDC. However, the present disclosure is not limited thereto. The light-emitting control signal drive part EDC and the at least one scan drive part SDC may be differently disposed according to the exemplary embodiment.

The data drive circuit DDC may be connected to the display panel DP in a tape-automated bonding (TAB) manner, connected to a bonding pad of the display panel DP in a chip-on-glass (COG) or chip-on-panel (COP) manner, or connected to the display panel DP in a chip-on-film (COF) manner.

The gate drive circuit GDC may be connected to the display panel DP in a tape-automated bonding (TAB) manner, connected to the bonding pad of the display panel DP in a chip-on-glass (COG) or chip-on-panel (COP) manner, or connected to the display panel DP in a chip-on-film (COF) manner. Alternatively, the gate drive circuit GDC may be formed as a gate1-in-panel (GIP) type in the non-display area NDA of the display panel DP. The gate drive circuit GDC may be disposed on the substrate or connected to the substrate. That is, in case that the gate drive circuit GDC is the GIP type, the gate drive circuit GDC may be disposed in the non-display area NDA of the substrate. In case that the gate drive circuit GDC is a chip-on-glass (COG) type, a chip-on-film (COF) type, or the like, the gate drive circuit GDC may be connected to the substrate.

Meanwhile, at least one of the data drive circuit DDC and the gate drive circuit GDC may be disposed in the display area DA of the display panel DP. For example, at least one of the data drive circuit DDC and the gate drive circuit GDC may be disposed so as not to overlap the subpixels SP or disposed to overlap some or all of the subpixels SP.

The data drive circuit DDC may be connected to one side (e.g., upper or lower side) of the display panel DP. Depending on operating methods, panel designing methods, or the like, the data drive circuits DDC may be connected to both the two opposite sides (e.g., upper and lower sides) of the display panel DP or connected to two or more side surfaces among the four side surfaces of the display panel DP.

The gate drive circuit GDC may be connected to one side (e.g., left or right side) of the display panel DP. Depending on operating methods, panel designing methods, or the like, the gate drive circuits GDC may be connected to both the two opposite sides (e.g., left and right sides) of the display panel DP or connected to two or more side surfaces among the four side surfaces of the display panel DP.

The display controller DCTR may be implemented as a component provided separately from the data drive circuit DDC or implemented as an integrated circuit by being integrated with the data drive circuit DDC.

The display controller DCTR may be a timing controller used for a typical display technology or may be a control device including a timing controller and configured to further perform other control functions. Alternatively, the display controller DCTR may be a control device different from a timing controller or may be a circuit disposed in a control device. The display controller DCTR may be implemented as an electronic component or various circuits such as integrated circuits (ICs), field programmable GATE1 arrays (FPGAs), application specific integrated circuits (ASICs), or processors.

The display controller DCTR may be mounted on a printed circuit board, a flexible printed circuit, or the like and electrically connected to the data drive circuit DDC and the gate drive circuit GDC through the printed circuit board, the flexible printed circuit, or the like.

The display controller DCTR may transmit a signal to the data drive circuit DDC and receive a signal from the data drive circuit DDC in accordance with one or more predetermined interfaces. In this case, for example, the interfaces may include a low-voltage differential signaling (LVDS) interface, an embedded clock point-to-point interface (EPI), a serial peripheral interface (SPI), and the like.

To further provide a touch sensing function in addition to the image display function, the display device 100 according to the exemplary embodiments of the present specification may include a touch sensor, and a touch sensing circuit configured to sense the touch sensor to detect whether a touch is made by a touch object such as a finger, a pen, or the like or to detect a touch position.

The touch sensing circuit may further include a touch drive circuit configured to operate the touch sensor, sense the touch sensor, and produce and output touch sensing data, and a touch controller configured to use the touch sensing data to detect the occurrence of a touch or a touch position.

The touch sensor may include a plurality of touch electrodes. The touch sensor may further include a plurality of touch lines configured to electrically connect the plurality of touch electrodes and the touch drive circuit.

The touch sensor may be provided in the form of a touch panel disposed outside the display panel DP or provided in the display panel DP. In case that the touch sensor is provided in the form of a touch panel present outside the display panel DP, the touch sensor is called an externally-carried touch sensor. In case that the touch sensor is an externally-carried touch sensor, the touch panel and the display panel DP may be separately manufactured and coupled to each other during an assembling process. The externally-carried touch panel may include a touch panel substrate, and the plurality of touch electrodes disposed on the touch panel substrate.

In case that the touch sensor is present inside the display panel DP, the touch sensor may be provided on the substrate SUB together with signal lines and electrodes related to a display operation during a process of manufacturing the display panel DP.

A touch drive circuit TDC may supply a touch driving signal to at least one of the plurality of touch electrodes, sense at least one of the plurality of touch electrodes, and produce touch sensing data.

The touch sensing circuit may perform touch sensing in a self-capacitance sensing manner or a mutual-capacitance sensing manner.

In case that the touch sensing circuit performs touch sensing in a self-capacitance sensing manner, the touch sensing circuit may perform the touch sensing on the basis of capacitance between each of the touch electrodes and the touch object (e.g., a finger, a pen, or the like).

According to the self-capacitance sensing manner, the plurality of touch electrodes may serve as a drive touch electrode and a sensing touch electrode. The touch drive circuit TDC may operate all or some of the plurality of touch electrodes and sense all or some of the plurality of touch electrodes.

In case that the touch sensing circuit performs touch sensing in a mutual-capacitance sensing manner, the touch sensing circuit may perform the touch sensing on the basis of capacitance between the touch electrodes.

According to the mutual-capacitance sensing manner, the plurality of touch electrodes is classified into drive touch electrodes and sensing touch electrodes. The touch drive circuit may operate the drive touch electrodes and sense the sensing touch electrodes.

The touch drive circuit and the touch controller, which are included in the touch sensing circuit, may be implemented as separate devices or a single device. In addition, the touch drive circuit and the data drive circuit DDC may be implemented as separate devices or a single device.

The display device 100 may further include a power supply circuit configured to supply various types of power to the display drive circuit and/or the touch sensing circuit.

The display device 100 according to the exemplary embodiments of the present specification may be a mobile terminal such as a smartphone or a tablet, or a monitor or a television (TV) having various sizes. However, the present disclosure is not limited thereto. The display device 100 may be one of the displays having various types and various sizes and being capable of displaying information or images.

As described above, the display area DA of the display panel DP may include the general area NA and the one or more optical areas DA1 and DA2.

The general area NA and the one or more optical areas DA1 and DA2 are areas in which images may be displayed. However, the general area NA is an area that does not require the light transmission structure, and the one or more optical areas DA1 and DA2 are areas that need to have the light transmission structures.

As described above, the display area DA of the display panel DP may include the one or more optical areas DA1 and DA2 together with the general area NA. However, for convenience of description, it is assumed that the display area DA includes both the first optical area DA1 and the second optical area DA2 (FIGS. 1C and 1D).

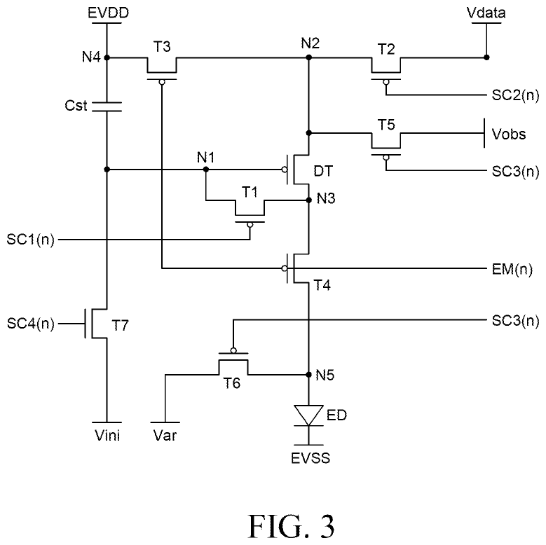

FIG. 3 is an equivalent circuit diagram of a subpixel of the display panel according to the exemplary embodiment of the present specification.

FIG. 3 exemplarily illustrates the pixel circuit for illustrative purposes only. The pixel circuit is not limited as long as the pixel circuit has a structure capable of controlling light emission of a light-emitting element ED (120) by applying a light-emitting signal EM(n). For example, the pixel circuit may include an additional scan signal, a switching thin-film transistor connected to the additional scan signal. An additional initialization voltage may be applied to the switching thin-film transistor. Connection relationships between switching elements and connection positions of capacitors may be variously set. Hereinafter, for convenience of description, the display device having a pixel circuit structure in FIG. 3 will be described.

With reference to FIG. 3, the plurality of subpixels SP may each include the pixel circuit having a driving transistor DT, and the light-emitting element ED (120) connected to the pixel circuit.

The subpixels SP, which are disposed in the general area NA, the first optical area DA1, and the second optical area DA2 included in the display area DA of the display panel DP, may each include the light-emitting element ED (120), the driving transistor DT configured to operate the light-emitting element ED (120), a plurality of scan transistors T1, T2, T3, T4, T5, T6, and T7 configured to operate the driving transistor DT, and a capacitor Cst configured to maintain a constant voltage for one frame.

The pixel circuit may operate the light-emitting element ED (120) by controlling a drive current flowing in the light-emitting element ED (120). The pixel circuit may include the driving transistor DT, the first to seventh transistors T1, T2, T3, T4, T5, T6, and T7, and the capacitor Cst. The transistors DT, T1, T2, T3, T4, T5, T6, and T7 may each include a first electrode, a second electrode, and a gate electrode. One of the first and second electrodes may be a source electrode, and the other of the first and second electrodes may be a drain electrode.

The transistors DT, T1, T2, T3, T4, T5, T6, and T7 may each be a P-type thin-film transistor or an N-type thin-film transistor. In the exemplary embodiment in FIG. 3, the first transistor T1 and the seventh transistor T7 are each configured as an N-type thin-film transistor, and the remaining transistors DT, T2, T3, T4, T5, and T6 are each configured as a P-type thin-film transistor. However, the present disclosure is not limited thereto. According to the exemplary embodiment, all or some of the transistors DT, T1, T2, T3, T4, T5, T6, and T7 may be the P-type thin-film transistors or the N-type thin-film transistors. In addition, the N-type thin-film transistor may be an oxide thin-film transistor, and the P-type thin-film transistor may be a polycrystalline silicon thin-film transistor.

Hereinafter, an example will be described in which the first transistor T1 and the seventh transistor T7 are each an N-type thin-film transistor, and the remaining transistors DT, T2, T3, T4, T5, and T6 are each a P-type thin-film transistor. Therefore, the first transistor T1 and the seventh transistor T7 are turned on by receiving high voltages, and the remaining transistors DT, T2, T3, T4, T5, and T6 are turned on by receiving low voltages.

For example, the first transistor T1, which constitutes the pixel circuit, may serve as a compensation transistor, the second transistor T2 may serve as a data supply transistor, the third and fourth transistors T3 and T4 may serve as light-emitting control transistors, the fifth transistor T5 may serve as a bias transistor, and the sixth and seventh transistors T6 and T7 may serve as initialization transistors.

The light-emitting element ED (120) may include an anode electrode and a cathode electrode. The anode electrode of the light-emitting element ED (120) may be connected to a fifth node N5, and the cathode electrode may be connected to a low-potential drive voltage EVSS.

The driving transistor DT may include the first electrode connected to a second node N2, the second electrode connected to a third node N3, and the gate electrode connected to a first node N1. The driving transistor DT may provide a drive current Id to the light-emitting element ED (120) on the basis of a voltage of the first node N1 (or a data voltage stored in the capacitor Cst to be described below).

The first transistor T1 may include the first electrode connected to the first node N1. the second electrode connected to the third node N3, and the gate electrode configured to receive a first scan signal SC1(n). The first transistor T1 may be turned on in response to the first scan signal SC1(n) and connected between the first node N1 (data voltage Vdata) and the third node N3 by means of a diode, such that the first transistor T1 may sample a threshold voltage Vth of the driving transistor DT. The first transistor T1 may be a compensation transistor.

The capacitor Cst may be connected or formed between the first node N1 and a fourth node N4. The capacitor Cst may store or maintain a provided high-potential drive voltage EVDD. In addition, in some instances, the capacitor Cst may further include one or more capacitors.

The second transistor T2 may include the first electrode connected to the data line DL (or configured to receive the data voltage Vdata), the second electrode connected to the second node N2, and the gate electrode configured to receive a second scan signal SC2(n). The second transistor T2 may be turned on in response to the second scan signal SC2(n) and transmit the data voltage Vdata to the second node N2. The second transistor T2 may be a data supply transistor.

The third and fourth transistors T3 and T4 (or the first and second light-emitting control transistors) may be connected between the high-potential drive voltage EVDD and the light-emitting element ED (120) and define a current flow path through which the drive current Id, which is generated by the driving transistor DT, flows.

The third transistor T3 may include the first electrode connected to the fourth node N4 and configured to receive the high-potential drive voltage EVDD, the second electrode connected to the second node N2, and the gate electrode configured to receive the light-emitting control signal EM(n).

The fourth transistor T4 may include the first electrode connected to the third node N3, the second electrode connected to the fifth node N5 (or the anode electrode of the light-emitting element ED (120)), and the gate electrode configured to receive the light-emitting control signal EM(n).

The third and fourth transistors T3 and T4 may be turned on in response to the light-emitting control signal EM(n). In this case, the drive current Id is provided to the light-emitting element ED (120), and the light-emitting element ED (120) may emit light with brightness corresponding to the drive current Id.

The fifth transistor T5 may include the first electrode configured to receive a bias voltage Vobs, the second electrode connected to the second node N2, and the gate electrode configured to receive a third scan signal SC3(n). The fifth transistor T5 may be a bias transistor.

The sixth transistor T6 may include the first electrode configured to receive a first initialization voltage Var, the second electrode connected to the fifth node N5, and the gate electrode configured to receive the third scan signal SC3(n).

Before the light-emitting element ED (120) emits light (or after the light-emitting clement ED (120) emits light), the sixth transistor T6 may be turned on in response to the third scan signal SC3(n) and initialize the anode electrode (or pixel electrode) of the light-emitting element ED (120) by using the first initialization voltage Var. The light-emitting element ED (120) may have a parasitic capacitor formed between the anode electrode and the cathode electrode. Further, the parasitic capacitor is charged while the light-emitting element ED (120) emits light, such that the anode electrode of the light-emitting element ED (120) may have a particular voltage. Therefore, it is possible to initialize a charge quantity accumulated in the light-emitting element ED (120) by applying the first initialization voltage Var to the anode electrode of the light-emitting element ED (120) through the sixth transistor T6.

In the present specification, the gate electrodes of the fifth and sixth transistor T5 and T6 are configured to receive the third scan signal SC3(n) in common. However, the present disclosure is not necessarily limited thereto. The gate electrodes of the fifth and sixth transistor T5 and T6 may be configured to be independently controlled by receiving separate scan signals.

The seventh transistor T7 may include the first electrode configured to receive a second initialization voltage Vini, the second electrode connected to the first node N1, and the gate electrode configured to receive a fourth scan signal SC4(n).

The seventh transistor T7 may be turned on in response to the fourth scan signal SC4(n) and initialize the gate electrode of the driving transistor DT by using the second initialization voltage Vini. Unnecessary electric charges may remain on the gate electrode of the driving transistor DT because of the high-potential drive voltage EVDD stored in the capacitor Cst. Therefore, it is possible to initialize the residual charge quantity by applying the second initialization voltage Vini to the gate electrode of the driving transistor DT through the seventh transistor T7.

Meanwhile, as described above, a differential pixel density designing method may be applied as one method of increasing the transmittance of at least one of the first optical area DA1 and the second optical area DA2. According to the differential pixel density designing method, the display panel DP may be designed so that the number of subpixels per unit area in at least one of the first optical area DA1 and the second optical area DA2 is smaller than the number of subpixels per unit area in the general area NA.

However, in some instances, alternatively, a differential pixel size designing method may be applied as another method of increasing the transmittance of at least one of the first optical area DA1 and the second optical area DA2. According to the differential pixel size designing method, the display panel DP may be designed so that the number of subpixels per unit area in at least one of the first optical area DA1 and the second optical area DA2 is equal or similar to the number of subpixels per unit area in the general area NA, and a size (i.e., light-emitting area size) of each of the subpixels SP disposed in at least one of the first optical area DA1 and the second optical area DA2 is smaller than a size (i.e., light-emitting area size) of each of the subpixels SP disposed in the general area NA.

Hereinafter, for convenience of description, the description will be made on the assumption that the differential pixel density designing method is applied between the two types of methods (the differential pixel density designing method and the differential pixel size designing method) of increasing the transmittance of at least one of the first optical area DA1 and the second optical area DA2.

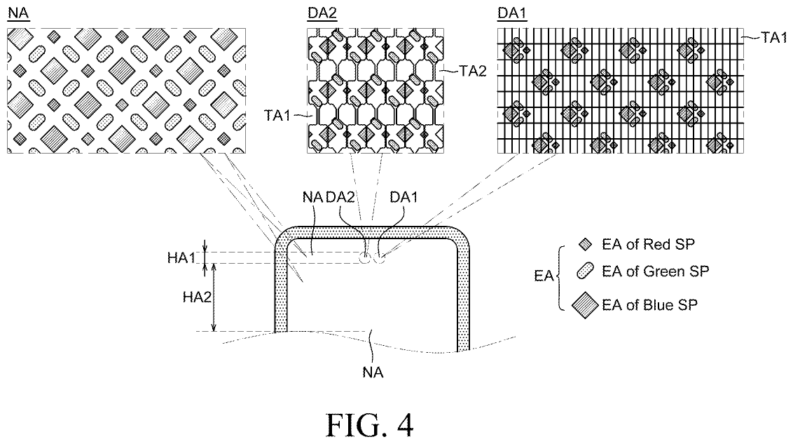

FIG. 4 is a view illustrating an arrangement of the subpixels in the display area of the display panel according to the exemplary embodiment of the present specification.

That is, FIG. 4 illustrates the arrangement of the subpixels SP in the three types of areas NA, DA1, and DA2 included in the display area of the display panel according to the exemplary embodiment of the present specification.

With reference to FIG. 4, the plurality of subpixels SP may be disposed in each of the general area NA, the first optical area DA1, and the second optical area DA2 included in the display area.

For example, the plurality of subpixels SP may include a red subpixel Red SP configured to emit red light, a green subpixel Green SP configured to emit green light, and a blue subpixel Blue SP configured to emit blue light.

Therefore, the general area NA, the first optical area DA1, and the second optical area DA2 may each include a light-emitting area EA for the red subpixel Red SP, a light-emitting area EA for the green subpixel Green SP, and a light-emitting area EA for the blue subpixel Blue SP.

With reference to FIG. 4, the general area NA may include the light-emitting area EA without including the light transmission structure.

However, the first optical area DA1 and the second optical area DA2 need to include the light transmission structure while including the light-emitting area EA.

Therefore, the first optical area DA1 may include the light-emitting area EA and a first transmissive area TA1, and the second optical area DA2 may include the light-emitting area EA and a second transmissive area TA2.

The light-emitting area EA and the transmissive areas TA1 and TA2 may be distinguished depending on whether light may be transmitted. That is, the light-emitting area EA may be an area that cannot transmit light, and the transmissive areas TA1 and TA2 may be areas that may transmit light.

In addition, the light-emitting area EA and the transmissive areas TA1 and TA2 may be distinguished depending on whether a particular metal layer is formed. For example, a cathode electrode may be formed in the light-emitting area EA, but no cathode electrode may be formed in the transmissive areas TA1 and TA2. In addition, a light-blocking layer may be formed in the light-emitting area EA, but no light-blocking layer may be formed in the transmissive areas TA1 and TA2.

In this case, the first optical area DA1 includes the first transmissive area TA1, and the second optical area DA2 includes the second transmissive area TA2, such that both the first optical area DA1 and the second optical area DA2 are areas that may transmit light.

In this case, the transmittance (degree of light transmission) of the first optical area DA1 and the transmittance (degree of light transmission) of the second optical area DA2 may be equal to each other.

In this case, the first transmissive area TA1 of the first optical area DA1 and the second transmissive area TA2 of the second optical area DA2 may be identical in shape or size. Alternatively, even though the first transmissive area TA1 of the first optical area DA1 and the second transmissive area TA2 of the second optical area DA2 are different in shape or size, a proportion of the first transmissive area TA1 in the first optical area DA1 and a proportion of the second transmissive area TA2 in the second optical area DA2 may be equal to each other.

Alternatively, the transmittance (degree of light transmission) of the first optical area DA1 and the transmittance (degree of light transmission) of the second optical area DA2 may be different from each other.

In this case, the first transmissive area TA1 of the first optical area DA1 and the second transmissive area TA2 of the second optical area DA2 may be different in shape or size. Alternatively, even though the first transmissive area TA1 of the first optical area DA1 and the second transmissive area TA2 of the second optical area DA2 are identical in shape or size, a proportion of the first transmissive area TA1 in the first optical area DA1 and a proportion of the second transmissive area TA2 in the second optical area DA2 may be different from each other.

For example, in case that the first optical-electronic device, which overlaps the first optical area DA1, is a camera and the second optical-electronic device, which overlaps the second optical area DA2, is a detection sensor, the camera may require a larger light amount than the detection sensor.

Therefore, the transmittance (degree of light transmission) of the first optical area DA1 may be higher than the transmittance (degree of light transmission) of the second optical area DA2.

In this case, the first transmissive area TA1 of the first optical area DA1 may have a larger size than the second transmissive area TA2 of the second optical area DA2. Alternatively, even though the first transmissive area TA1 of the first optical area DA1 and the second transmissive area TA2 of the second optical area DA2 are identical in size, a proportion of the first transmissive area TA1 in the first optical area DA1 may be larger than a proportion of the second transmissive area TA2 in the second optical area DA2.

Hereinafter, for convenience of description, an example will be described in which the transmittance (degree of light transmission) of the first optical area DA1 is higher than the transmittance (degree of light transmission) of the second optical area DA2.

In addition, as illustrated in FIG. 4, in the exemplary embodiment of the present specification, the transmissive areas TA1 and TA2 may each be referred to as a transparent area, and the transmittance may be referred to as transparency.

In addition, as illustrated in FIG. 4, in the exemplary embodiment of the present specification, it is assumed that the first optical area DA1 and the second optical area DA2 are positioned at an upper end of the display area of the display panel and disposed side by side in a leftward/rightward direction.

With reference to FIG. 4, a horizontal display area, in which the first optical area DA1 and the second optical area DA2 are disposed, is referred to as a first horizontal display area HA1, and a horizontal display area, in which the first optical area DA1 and the second optical area DA2 are not disposed, is referred to as a second horizontal display area HA2.

With reference to FIG. 4, the first horizontal display area HA1 may include the general area NA, the first optical area DA1, and the second optical area DA2. In contrast, the second horizontal display area HA2 may include only the general area NA.

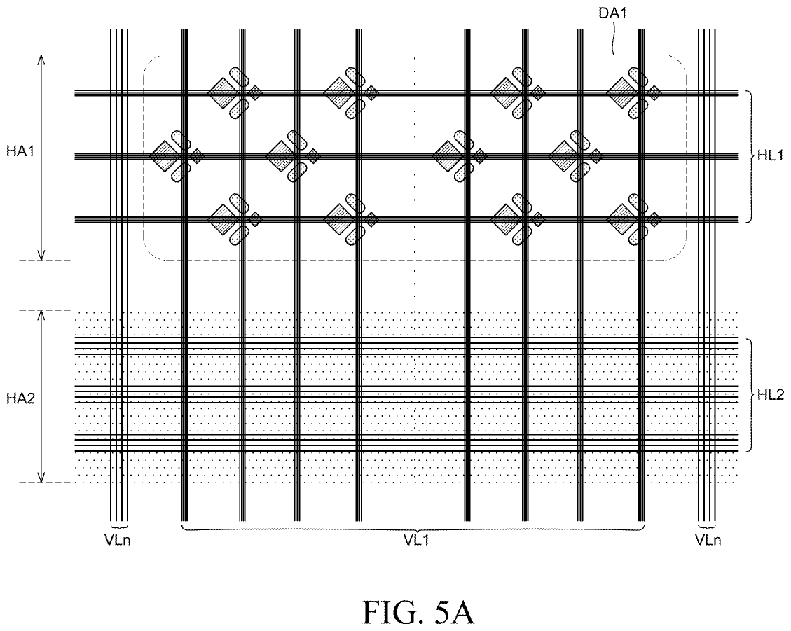

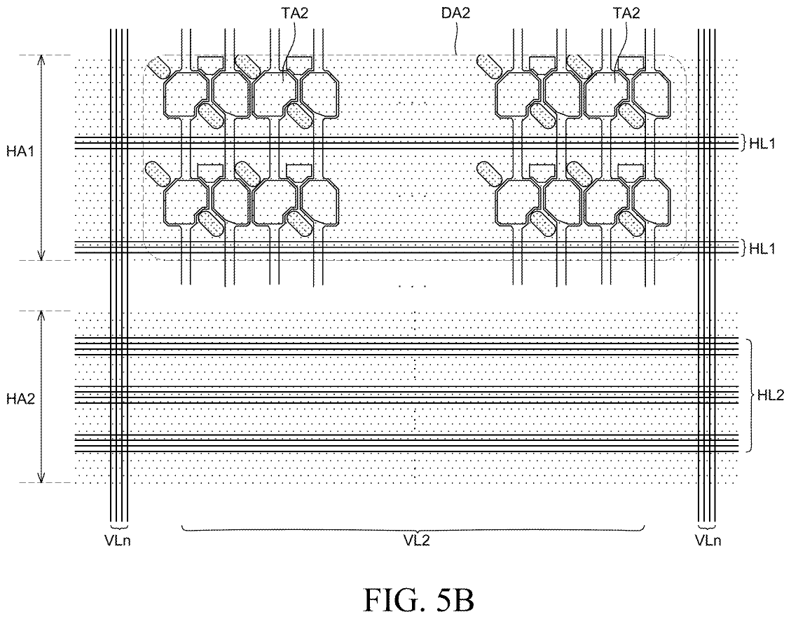

FIG. 5A is a view illustrating an example of an arrangement of the signal lines in the first optical area and the general area of the display panel according to the exemplary embodiment of the present specification.

FIG. 5B is a view illustrating an example of an arrangement of the signal lines in the second optical area and the general area of the display panel according to the exemplary embodiment of the present specification.

That is, FIG. 5A illustrates the arrangement of the signal lines in the first optical area DA1 and the general area NA of the display panel according to the exemplary embodiment of the present specification. FIG. 5B illustrates the arrangement of the signal lines in the second optical area DA2 and the general area NA of the display panel according to the exemplary embodiment of the present specification.

The first horizontal display area HA1 illustrated in FIGS. 5A and 5B is a part of the first horizontal display area HA1 of the display panel DP, and the second horizontal display area HA2 is a part of the second horizontal display area HA2 of the display panel.

The first optical area DA1 illustrated in FIG. 5A is a part of the first optical area DA1 of the display panel, and the second optical area DA2 illustrated in FIG. 5B is a part of the second optical area DA2 of the display panel.

With reference to FIGS. 5A and 5B, the first horizontal display area HA1 may include the general area, the first optical area DA1, and the second optical area DA2. The second horizontal display area HA2 may include the general area.

Various types of horizontal lines HL1 and HL2 and various types of vertical lines VLn, VL1, and VL2 may be disposed on the display panel.

In the exemplary embodiment of the present specification, a horizontal direction and a vertical direction may mean two directions intersecting each other. The horizontal direction and the vertical direction may be different from each other in a viewing direction. For example, in the exemplary embodiment of the present specification, the horizontal direction may mean a direction in which one gate line is disposed while extending, and the vertical direction may mean a direction in which one data line is disposed while extending. As described above, the horizontal and vertical directions will be described, for example.

With reference to FIGS. 5A and 5B, horizontal lines disposed on the display panel may include a first horizontal line HL1 disposed in the first horizontal display area HA1, and a second horizontal line HL2 disposed in the second horizontal display area HA2.

The horizontal line disposed on the display panel may be the gate line. That is, the first horizontal line HL1 and the second horizontal line HL2 may each be the gate line. The gate line may include various types of gate lines in accordance with the structure of the subpixel.

With reference to FIGS. 5A and 5B, the vertical line disposed on the display panel may include a general vertical line VLn disposed only in the general area, a first vertical line VL1 configured to pass through both the first optical area DA1 and the general area, and a second vertical line VL2 configured to pass through both the second optical area DA2 and the general area.

The vertical line disposed on the display panel may include a data line, a drive voltage line, and the like. Further, the vertical line may further include a reference voltage line, an initialization voltage line, and the like. That is, the general vertical line VLn, the first vertical line VL1, and the second vertical line VL2 may each include the data line, the drive voltage line, and the like and further include the reference voltage line, the initialization voltage line, and the like.

In the exemplary embodiment of the present specification, the term “horizontal” used in the second horizontal line HL2 merely means that a signal is transmitted from the left side (or right side) to the right side (or left side) but does not mean that the second horizontal line HL2 extends in a straight shape only in an accurately horizontal direction. That is, FIGS. 5A and 5B illustrate that the second horizontal line HL2 has a straight shape. However, alternatively, the second horizontal line HL2 may include a bent or curved portion. Likewise, the first horizontal line HL1 may also include a bent or curved portion.

In the exemplary embodiment of the present specification, the term “vertical” in the general vertical line VLn merely means that a signal is transmitted from the upper side (or lower side) to the lower side (or upper side) but does not mean that the general vertical line VLn extends in a straight shape only in an accurately vertical direction. That is, FIGS. 5A and 5B illustrate that the general vertical line VLn has a straight shape. However, alternatively, the general vertical line VLn may include a bent or curved portion. Likewise, the first vertical line VL1 and the second vertical line VL2 may each also include a bent or curved portion.

With reference to FIG. 5A, the first optical area DA1 included in the first horizontal area HA1 may include the light-emitting area and the first transmissive area. In the first optical area DA1, an outer area of the first transmissive area may include the light-emitting area.

With reference to FIG. 5A, to improve the transmittance of the first optical area DA1, the first horizontal line HL1 passing through the first optical area DA1 may extend while bypassing the first transmissive area in the first optical area DA1.

Therefore, the first horizontal line HL1 passing through the first optical area DA1 may include a curved section, a bending section, or the like that bypasses a portion disposed outside an outer peripheral rim of the first transmissive area.

Therefore, the first horizontal line HL1 disposed in the first horizontal area HA1 and the second horizontal line HL2 disposed in the second horizontal area HA2 may be different in shape or length. That is, the first horizontal line HL1, which passes through the first optical area DA1, and the second horizontal line HL2, which does not pass through the first optical area DA1, may be different in shape or length.

In addition, to improve the transmittance of the first optical area DA1, the first vertical line VL1 passing through the first optical area DA1 may extend while bypassing the first transmissive area in the first optical area DA1.

Therefore, the first vertical line VL1 passing through the first optical area DA1 may include a curved section, a bending section, or the like that bypasses a portion disposed outside the outer peripheral rim of the first transmissive area.

Therefore, the first vertical line VL1, which passes through the first optical area DA1. and the general vertical line VLn, which is disposed in the general area without passing through the first optical area DA1, may be different in shape or length.

With reference to FIG. 5A, the first transmissive areas included in the first optical area DA1 in the first horizontal area HA1 may be arranged in an oblique direction.

With reference to FIG. 5A, the light-emitting area may be disposed between the two first transmissive areas, which are disposed adjacent to each other in the leftward/rightward direction, in the first optical area DA1 in the first horizontal area HA1. The light-emitting area may be disposed between the two first transmissive areas, which are disposed adjacent to each other in the upward/downward direction, in the first optical area DA1 in the first horizontal area HA1.

With reference to FIG. 5A, all the first horizontal lines HL1 disposed in the first horizontal area HA1, i.e., all the first horizontal lines HL1 passing through the first optical area DA1 may each include at least one of a curved section and a bending section that bypass the portion disposed outside the outer peripheral rim of the first transmissive area.

With reference to FIG. 5B, the second optical area DA2 included in the first horizontal area HA1 may include the light-emitting area and the second transmissive area TA2. In the second optical area DA2, an outer area of the second transmissive area TA2 may include the light-emitting area.

The positions and arrangement states of the light-emitting area and the second transmissive area TA2 in the second optical area DA2 may be identical to the positions and arrangement states of the light-emitting area and the second transmissive area in the first optical area DA1 in FIG. 5A.

Alternatively, as illustrated in FIG. 5B, the positions and arrangement states of the light-emitting area and the second transmissive area TA2 in the second optical area DA2 may be different from the positions and arrangement states of the light-emitting area and the second transmissive area in the first optical area DA1 in FIG. 5A.

For example, with reference to FIG. 5B, the second transmissive areas TA2 may be arranged in the horizontal direction (leftward/rightward direction) in the second optical area DA2. No light-emitting area may be disposed between the two second transmissive areas TA2 disposed adjacent to each other in the horizontal direction (leftward/rightward direction). In addition, the light-emitting area in the second optical area DA2 may be disposed between the second transmissive areas TA2 disposed adjacent to each other in the vertical direction (upward/downward direction). That is, the light-emitting area may be disposed between the two rows of the second transmissive areas TA2.

The first horizontal line HL1 may pass through the second optical area DA2 in the first horizontal area HA1 and the general area at the periphery of the second optical area DA2 in the same shape as illustrated in FIG. 5A.

Alternatively, as illustrated in FIG. 5B, the first horizontal line HL1 may pass through the second optical area DA2 in the first horizontal area HA1 and the general area at the periphery of the second optical area DA2 in a shape different from the shape illustrated in FIG. 5A.

That is, this is because the positions and arrangement states of the light-emitting area and the second transmissive area TA2 in the second optical area DA2 in FIG. 5B are different from the positions and arrangement states of the light-emitting area and the second transmissive area in the first optical area DA1 in FIG. 5A.

With reference to FIG. 5B, when the first horizontal line HL1 passes through the second optical area DA2 in the first horizontal area HA1 and the general area at the periphery of the second optical area DA2, the first horizontal line HL1 may pass in a straight shape, without having a curved section or a bending section, between the second transmissive areas TA2 disposed adjacent to each other in the upward/downward direction.

In other words, one first horizontal line HL1 has a curved section or a bending section in the first optical area DA1 but may not have a curved section or a bending section in the second optical area DA2.

To improve the transmittance of the second optical area DA2, the second vertical line VL2 passing through the second optical area DA2 may extend while bypassing the second transmissive area TA2 in the second optical area DA2.

Therefore, the second vertical line VL2 passing through the second optical area DA2 may include a curved section, a bending section, or the like that bypasses a portion disposed outside an outer peripheral rim of the second transmissive area TA2.

Therefore, the second vertical line VL2, which passes through the second optical area DA2, and the general vertical line VLn, which is disposed in the general area without passing through the second optical area DA2, may be different in shape or length.

As illustrated in FIG. 5A, the first horizontal line HL1 passing through the first optical area DA1 may include curved sections, bending sections, or the like that bypass portions disposed outside the outer peripheral rim of the first transmissive area.

Therefore, a length of the first horizontal line HL1, which passes through the first optical area DA1 and the second optical area DA2, may be slightly longer than a length of the second horizontal line HL2 that is disposed only in the general area without passing through the first optical area DA1 and the second optical area DA2.

Therefore, resistance (hereinafter, referred to as first resistance) of the first horizontal line HL1, which passes through the first optical area DA1 and the second optical area DA2, may be slightly higher than resistance (hereinafter, referred to as second resistance) of the second horizontal line HL2 that is disposed only in the general area without passing through the first optical area DA1 and the second optical area DA2.

With reference to FIGS. 5A and 5B, according to the light transmission structure, the first optical area DA1, which at least partially overlaps the first optical-electronic device 170a includes the plurality of first transmissive areas TA1, and the second optical area DA2, which at least partially overlaps the second optical-electronic device 170b, includes the plurality of second transmissive areas TA2. Therefore, the number of subpixels per unit area in each of the first optical area DA1 and the second optical area DA2 may be smaller than the number of subpixels per unit area in the general area NA.

The number of subpixels, to which the first horizontal line HL1 passing through the first optical area DA1 and the second optical area DA2 is connected, may be different from the number of subpixels to which the second horizontal line HL2, which is disposed only in the general area NA without passing through the first optical area DA1 and the second optical area DA2, is connected.

The number of (the first number of) subpixels, to which the first horizontal line HL1 passing through the first optical area DA1 and the second optical area DA2 is connected, may be smaller than the number of (the second number of) subpixels to which the second horizontal line HL2, which is disposed only in the general area without passing through the first optical area DA1 and the second optical area DA2, is connected.

A difference between the first number and the second number may vary depending on a difference between the resolution of each of the first optical area DA1 and the second optical area DA2 and the resolution of the general area. For example, the difference between the first number and the second number may increase as the difference between the resolution of each of the first optical area DA1 and the second optical area DA2 and the resolution of the general area increases.

Because the number of (the first number of) subpixels, to which the first horizontal line HL1 passing through the first optical area DA1 and the second optical area DA2 is connected, is smaller than the number of (the second number of) subpixels to which the second horizontal line HL2, which is disposed only in the general area without passing through the first optical area DA1 and the second optical area DA2, is connected as described above, an area, in which the first horizontal line HL1 overlaps other peripheral electrodes or lines, may be smaller than an area in which the second horizontal line HL2 overlaps other peripheral electrodes or lines.

Therefore, the parasitic capacitance (hereinafter, referred to as first capacitance) formed between the first horizontal line HL1 and other peripheral electrodes or lines may be greatly lower than the parasitic capacitance (hereinafter, referred to as second capacitance) formed between the second horizontal line HL2 and other peripheral electrodes or lines.

In consideration of a high-low relationship between the first resistance and the second resistance (first resistance>second resistance) and a high-low relationship between the first capacitance and the second capacitance (first capacitance<<second capacitance), a resistance-capacitance (RC) value (hereinafter, referred to as a first RC value) of the first horizontal line HL1 passing through the first optical area DA1 and the second optical area DA2 may be much smaller than an RC value (hereinafter, referred to as a second RC value) of the second horizontal line HL2 that is disposed only in the general area without passing through the first optical area DA1 and the second optical area DA2 (first RC value<<second RC value).

The signal transmission properties through the first horizontal line HL1 and the signal transmission properties through the second horizontal line HL2 may be changed by a difference (hereinafter, referred to as an RC load deviation) between the first RC value of the first horizontal line HL1 and the second RC value of the second horizontal line HL2.

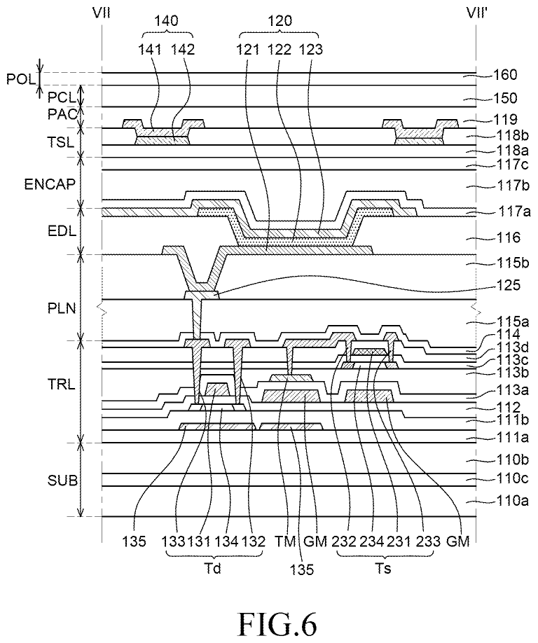

Hereinafter, a cross-sectional structure of the general area NA of the display device 100 will be described in more detail with reference to FIG. 6.

FIG. 6 is a cross-sectional view illustrating a cross-sectional structure of one pixel area disposed in the general area according to the exemplary embodiment of the present specification.

In the general area NA, a transistor layer TRL may be disposed on an upper portion of the substrate SUB, and a planarization layer PLN may be disposed on an upper portion of the transistor layer TRL. In addition, a light-emitting element layer EDL may be disposed on an upper portion of the planarization layer PLN, a sealing layer ENCAP may be disposed on an upper portion of the light-emitting element layer EDL, a touch sensing layer TSL may be disposed on an upper portion of the sealing layer ENCAP, and a protective layer PAC may be disposed on an upper portion of the touch sensing layer TSL. In addition, an organic material layer PCL may be disposed on an upper portion of the protective layer PAC, and a polarizing layer POL may be disposed on an upper portion of the organic material layer PCL.

The substrate SUB is a component for supporting various constituent elements included in the display device 100 and may be made of an insulating material. The substrate SUB may include a first substrate 110a, a second substrate 110b, and an interlayer insulation film 110c. The interlayer insulation film 110c may be disposed between the first substrate 110a and the second substrate 110b. As described above, the substrate SUB is configured by the first substrate 110a, the second substrate 110b, and the interlayer insulation film 110c, which may suppress moisture penetration. For example, the first substrate 110a and the second substrate 110b may each be a substrate made of polyimide (PI).

Various types of patterns 131, 132, 133, 134, 231, 232, 233, and 234, various types of insulation films 111a, 111b, 112, 113a, 113b, and 114, and various types of metal patterns TM, GM, and 135 may be disposed on the transistor layer TRL in the general area NA in order to form transistors such as the driving transistor DT and at least one switching transistor Ts and form transistors such as at least one capacitor.

Hereinafter, a layered structure of the transistor layer TRL will be described in more detail.

A multi-buffer layer 111a may be disposed on the second substrate 110b, and an active buffer layer 111b may be disposed on the multi-buffer layer 111a.

A metal layer 135 may be disposed on the multi-buffer layer 111a.

In this case, the metal layer 135 may serve as a light shield and be also referred to as a light-blocking layer.

The active buffer layer 111b may be disposed on the metal layer 135.

A first active layer 134 of the driving transistor DT may be disposed on the active buffer layer 111b. For example, the first active layer 134 may be made of polycrystalline silicon (p-Si), amorphous silicon (a-Si), or an oxide semiconductor. However, the present disclosure is not limited thereto. Meanwhile, the driving transistor DT is formed on the active buffer layer 111b and includes the first active layer 134, a first gate insulation film 112 configured to cover the first active layer 134, a first gate electrode 131 disposed on the first gate insulation film 112, a first interlayer insulation film 113a configured to cover the first gate electrode 131, a second gate insulation film 113b disposed on the first interlayer insulation film 113a, a third interlayer insulation film 113c disposed on the second gate insulation film 113b, a first source electrode 132 and a first drain electrode 133 disposed on the third interlayer insulation film 113c.

The first gate insulation film 112 may be disposed on the first active layer 134. The first gate insulation film 112 may be made of silicon oxide (SiOx), silicon nitride (SiNx), or a multilayer thereof.

In addition, the first gate electrode 131 of the driving transistor DT may be disposed on the first gate insulation film 112. The first gate electrode 131 is disposed on the first gate insulation layer 112 and overlaps the first active layer 134. The first gate electrode 131 may be made of various electrically conductive materials, for example, magnesium (Mg), aluminum (Al), nickel (Ni), chromium (Cr), molybdenum (Mo), tungsten (W), gold (Au), or an alloy thereof. However, the present disclosure is not limited thereto.

A gate material layer GM may be disposed on the first gate insulation film 112 and provided at a position different from a position at which the driving transistor DT is formed.

The first interlayer insulation film 113a may be disposed on the first gate electrode 131 and the gate material layer GM. A metal pattern TM may be disposed on the first interlayer insulation film 113a. A second interlayer insulation film 113b may be disposed while covering the metal pattern TM on the first interlayer insulation film 113a.

The second interlayer insulation film 113b provides a base that may form a second active layer 234 and space the second active layer 234 from the first active layer 134.

The second active layer 234 of the switching transistor Ts may be disposed on the second interlayer insulation film 113b. For example, the second active layer 234 may be made of polycrystalline silicon, amorphous silicon, or an oxide semiconductor. However, the present disclosure is not limited thereto.

A second gate insulation film 113c may be disposed on the second active layer 234. In addition, a second gate electrode 231 of the switching transistor Ts is disposed on the second gate insulation film 113c. The second gate electrode 231 is disposed on the second gate insulation film 113c and overlaps the second active layer 234.

The second gate insulation film 113c covers the second active layer 234 of the switching transistor Ts. The second gate insulation film 113c is implemented as an inorganic film because the second gate insulation film 113c is formed on the second active layer 234. For example, the second gate insulation film 113c may be made of silicon oxide (SiO₂), silicon nitride (SiNx), or a multilayer thereof.

The second gate electrode 231 may be made of a metallic material. For example, the second gate electrode 231 may be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

Meanwhile, the switching transistor Ts is formed on the second interlayer insulation film 113b and includes the second active layer 234, the second gate insulation film 113c configured to cover the second active layer 234, the second gate electrode 231 disposed on the second gate insulation film 113c, the third interlayer insulation film 113c configured to cover the second gate electrode 231, and a second source electrode 232 and a second drain electrode 233 disposed on the third interlayer insulation film 113c.

The switching transistor Ts may further include the gate material layer GM positioned on a lower portion of the first interlayer insulation film 113a and configured to overlap the second active layer 234. The gate material layer GM may block light entering the second active layer 234, thereby ensuring the reliability of the switching transistor Ts. The gate material layer GM may be made of the same material as the first gate electrode 131 and formed on a top surface of the first gate insulation film 112. The gate material layer GM may be electrically connected to the second gate electrode 234 and constitute a dual gate. The first source electrode 132 and the first drain electrode 133 of the driving transistor DT and the second source electrode 232 and the second drain electrode 233 of the switching transistor Ts may be disposed on a third interlayer insulation film 113d.

The second source electrode 232 and the second drain electrode 233 may be formed on the third interlayer insulation film 113d and made of the same material as the first source electrode 132 and the first drain electrode 133, thereby reducing the number of mask processes.

The first source electrode 132 and the first drain electrode 133 may be respectively connected to one side and the other side of the first active layer 134 through contact holes provided in the third interlayer insulation film 113d, the second gate insulation film 113c, the second interlayer insulation film 113b, the first interlayer insulation film 113a, and the first gate insulation film 112.

The second source electrode 232 and the second drain electrode 233 may be respectively connected to one side and the other side of the second active layer 234 through contact holes provided in the third interlayer insulation film 113d and the second gate insulation film 113c.

The first source electrode 132, the first drain electrode 133, the second source electrode 232, and the second drain electrode 233 may each be configured as a single layer or multilayer made of various electrically conductive materials, for example, magnesium (Mg), aluminum (Al), nickel (Ni), chromium (Cr), molybdenum (Mo), tungsten (W), gold (Au), or an alloy thereof. However, the present disclosure is not limited thereto.

A portion of the first active layer 134, which overlaps the first gate electrode 131, is a channel area. One of the first source electrode 132 and the first drain electrode 133 is connected to one side of the channel area of the first active layer 134, and the other of the first source electrode 132 and the first drain electrode 133 is connected to the other side of the channel area of the first active layer 134. The second active layer 234 may be configured in the same shape as the first active layer 134. In case that the second active layer 234 is implemented by an oxide semiconductor material, the second active layer 234 includes a genuine second channel area, which is not doped with impurities, and a second source area and a second drain area that are doped with impurities and thus have conductivity.

A passivation layer 114 may be disposed on the first source electrode 132, the first drain electrode 133, the second source electrode 232, and the second drain electrode 233. The passivation layer 114 may serve to protect the driving transistor DT and be made of an inorganic film, for example, silicon oxide (SiOx), silicon nitride (SiNx), or a multilayer thereof.

Meanwhile, the gate material layer GM and the metal pattern TM may be disposed on the first gate insulation film 112 while overlapping each other, thereby implementing the capacitor Cst. For example, the metal pattern TM may be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof.

The capacitor Cst stores the data voltage applied through the data line DL for a predetermined period of time and provides the data voltage to the light-emitting element ED (120). The capacitor Cst includes two electrodes, which corresponds to each other, and a dielectric material between the two electrodes. The first interlayer insulation film 113a is positioned between the gate material layer GM and the metal pattern TM.

The gate material layer GM or the metal pattern TM of the capacitor Cst may be electrically connected to the second source electrode 232 or the second drain electrode 233 of the switching transistor Ts. However, the present disclosure is not limited thereto. A connection relationship of the capacitor Cst may vary depending on the pixel drive circuit.

In addition, the metal layer 135 may be additionally disposed on the multi-buffer layer 111a to overlap the gate material layer GM and the metal pattern TM, thereby constituting the dual capacitor Cst.

In the exemplary embodiment of the present specification, the at least one switching transistor Ts has an active layer made of an oxide semiconductor. The transistor having the active layer made of an oxide semiconductor provides an excellent effect of blocking a leakage current and requires a relatively low manufacturing cost in comparison with a transistor having an active layer made of polycrystalline silicon. Therefore, the pixel circuit according to the exemplary embodiment of the present specification includes a driving transistor or at least one switching transistor made of an oxide semiconductor material in order to reduce power consumption and manufacturing costs.

All the transistors, which include the driving transistor and constitute the pixel circuit, may each have the active layer made of an oxide semiconductor. Alternatively, only some transistors may be implemented by using an oxide semiconductor.

However, the transistor implemented by using an oxide semiconductor hardly ensures the reliability. The transistor implemented by using polycrystalline silicon may provide a high operating speed and excellent reliability. Therefore, the exemplary embodiment of the present specification includes both the transistor implemented by using an oxide semiconductor and the transistor implemented by using polycrystalline silicon. However, the present disclosure is not limited thereto. Only the transistor implemented by using an oxide semiconductor or only the transistor implemented by using polycrystalline silicon may be applied to constitute the pixel circuit in accordance with design.

The planarization layer PLN may be disposed on the upper portion of the transistor layer TRL.

The planarization layer PLN may include a first planarization layer 115a and a second planarization layer 115b. The planarization layer PLN protects the driving transistor DT and planarizes the upper portion of the driving transistor DT.

The first planarization layer 115a may be disposed on the passivation layer 114.

A connection electrode 125 may be disposed on the first planarization layer 115a.

The connection electrode 125 may be connected to one of the first source electrode 132 and the first drain electrode 133 through a contact hole provided in the first planarization layer 115a.

The second planarization layer 115b may be disposed on the connection electrode 125.

The light-emitting element layer EDL may be positioned on an upper portion of the second planarization layer 115b.

Hereinafter, a layered structure of the light-emitting element layer EDL will be described in detail.

An anode 121 may be disposed on the second planarization layer 115b. In this case, the anode 121 may be electrically connected to the connection electrode 125 through a contact hole provided in the second planarization layer 115b. The anode 121 may be made of a metallic material.

In case that the display device 100 is a top-emission type display device in which light emitted from the light-emitting element ED (120) propagates toward an upper side of the substrate SUB on which the light-emitting element ED (120) is disposed, the anode 121 may further include a transparent conductive layer, and a reflective layer disposed on the transparent conductive layer. For example, the transparent conductive layer may be made of transparent conducting oxide such as ITO or IZO. For example, the reflective layer may be made of silver (Ag), aluminum (Al). gold (Au), molybdenum (Mo), tungsten (W), chromium (Cr), or an alloy thereof.

A bank 116 may be disposed while covering the anode 121. A portion of the bank 116, which corresponds to the light-emitting area of the subpixel, may be opened. A part of the anode 121 may be exposed through the opened portion (hereinafter, referred to as an open area) of the bank 116. In this case, the bank 116 may be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto.

Although not illustrated, a spacer may be further positioned on the bank 116. The spacer may be made of the same material as the bank 116.

A light-emitting layer 122 may be disposed in the open area of the bank 116 and an area at the periphery of the open area. Therefore, the light-emitting layer 122 may be disposed on the anode 121 exposed through the open area of the bank 116.

A cathode 123 may be disposed on the light-emitting layer 122.

The light-emitting element ED (120) may be formed by the anode 121, the light-emitting layer 122, and the cathode 123. The light-emitting layer 122 may include a plurality of organic films.

The sealing layer ENCAP may be positioned on the upper portion of the light-emitting element layer EDL.

The sealing layer ENCAP may have a single-layer structure or a multilayer structure. For example, the sealing layer ENCAP may include a first sealing layer 117a, a second sealing layer 117b, and a third sealing layer 117c.

In this case, the first sealing layer 117a and the third sealing layer 117c may each be made of an inorganic film, and the second sealing layer 117b may be made of an organic film. Among the first sealing layer 117a, the second sealing layer 117b, and the third sealing layer 117c, the second sealing layer 117b may be thickest and serve as a planarization layer.

The first sealing layer 117a may be disposed on the cathode 123 and closest to the light-emitting element ED (120). The first sealing layer 117a may be made of an inorganic insulating material that may be deposited at a low temperature. For example, the first sealing layer 117a may be made of silicon nitride (SiNx), silicon oxide (SiOx), oxidation silicon nitride (SiON), aluminum oxide (Al₂O₃), or the like. Because the first sealing layer 117a is deposited in a low-temperature ambience, it is possible to suppress damage to the light-emitting layer 122 made of an organic material vulnerable to a high-temperature ambience during a deposition process.

The second sealing layer 117b may have a smaller area than the first sealing layer 117a. In this case, the second sealing layer 117b may be formed to expose two opposite ends of the first sealing layer 117a. The second sealing layer 117b may serve as a buffer for mitigating stress between the layers caused when the flexible display device is bent. The second sealing layer 117b may serve to improve the planarization performance.

For example, the second sealing layer 117b may be made of an organic insulating material such as acrylic resin, epoxy resin, polyimide, polyethylene, or silicon oxycarbon (SiOC). For example, the second sealing layer 117b may also be formed in an inkjet manner. However, the present disclosure is not limited thereto.

The third sealing layer 117c may be formed on the upper portion of the substrate SUB having the second sealing layer 117b to cover a top surface and a side surface of each of the second sealing layer 117b and the first sealing layer 117a. In this case, the third sealing layer 117c may minimize or block the penetration of outside moisture or oxygen into the first sealing layer 117a and the second sealing layer 117b. For example, the third sealing layer 117c may be made of an inorganic insulating material such as silicon nitride (SiNx), silicon oxide (SiOx), oxidation silicon nitride (SiON), or aluminum oxide (Al₂O₃).

Although not illustrated, a color filter may be disposed on the sealing layer ENCAP. However, the present disclosure is not limited thereto.

The touch sensing layer TSL may be disposed on the upper portion of the sealing layer ENCAP.

A touch buffer film 118a may be disposed on the upper portion of the sealing layer ENCAP, a touch line 140 may be disposed on the touch buffer film 118a.

The touch line 140 may include a touch sensor metal 141 and a bridge metal 142 positioned on different layers. A touch interlayer insulation film 118b may be disposed between the touch sensor metal 141 and the bridge metal 142.

For example, the touch sensor metal 141 may include a first touch sensor metal, a second touch sensor metal, and a third touch sensor metal that are disposed adjacent to one another. The first touch sensor metal and the second touch sensor metal may be electrically connected to each other. However, in case that the third touch sensor metal is present between the first touch sensor metal and the second touch sensor metal, the first touch sensor metal and the second touch sensor metal may be electrically connected to each other through the bridge metal 142 present on a layer different from the layer on which the first touch sensor metal and the second touch sensor metal are disposed. The bridge metal 142 may be insulated from third touch sensor metal by the touch interlayer insulation film 118b.

During a process of forming the touch sensing layer TSL, a liquid chemical (a developer, an etching liquid, or the like) used for the process may be produced, or moisture or the like may be produced from the outside. The touch buffer film 118a may be disposed, and the touch sensing layer TSL may be disposed on the touch buffer film 118a, which may inhibit moisture or a liquid chemical, which is produced during the process of manufacturing the touch sensing layer TSL, from penetrating into the light-emitting layer 122 including an organic material. Therefore, the touch buffer film 118a may suppress damage to the light-emitting layer 122 vulnerable to a liquid chemical or moisture.

To suppress damage to the light-emitting layer 122 including an organic material vulnerable to a high temperature, the touch buffer film 118a may be made of an organic insulating material that may be formed at a predetermined low temperature (e.g., 100° C. or less) and have low permittivity of 1 to 3. For example, the touch buffer film 118a may be made of an acrylic-based, epoxy-based, or siloxane-based material. When the flexible display device is bent, the sealing layer ENCAP may be damaged, and the touch sensor metal 141 positioned on an upper portion of the touch buffer film 118a may be broken. The touch buffer film 118a, which is made of an organic insulating material and has the planarization performance may suppress damage to the sealing layer ENCAP and inhibit the metals 141 and 142, which constitute the touch line 140, from being broken even though the flexible display device is bent.

A protective layer PAC (119) may be disposed to cover the touch line 140. The protective layer 119 may be made of an organic insulation film.

An organic material layer PCL (150) is disposed to cover the protective layer 119.

In case that only the protective layer 119 made of an organic insulation film is disposed on an uppermost layer of the display device 100, only the protective layer 119 cannot perfectly compensate for a level difference caused by the touch sensing layer TSL disposed on a lower portion of the protective layer 119, which may cause a problem in that the user visually recognizes a stain caused by the touch line 140.

The organic material layer 150 made of an organic insulation film is additionally disposed on the upper portion of the protective layer 119, which may improve the visibility of the display device 100 by suppressing a level difference on the uppermost layer of the display device 100.

The organic material layer 150 may be made of the same material as the second scaling layer 117b of the sealing layer ENCAP. For example, the organic material layer 150 may be made of an organic insulating material such as acrylic resin, epoxy resin, polyimide, polyethylene, or silicon oxycarbon (SiOC). The organic material layer 150 may also be formed in an inkjet manner. However, the present disclosure is not limited thereto.

A polarizing layer POL (160) is disposed on the organic material layer 150.

The polarizing layer 160 suppresses reflection of external light in the display area DA of the substrate SUB. In case that the display device 100 is used outside, external natural light may be introduced and reflected by the reflective layer included in the anode 121 of the light-emitting element or reflected by an electrode made of metal and disposed on a lower portion of the light-emitting element 120. The light beams, which are reflected as described above, may inhibit an image on the display device 100 from being visually recognized. The polarizing layer 160 may polarize, in a particular direction, the light introduced from the outside, thereby inhibiting the reflected light from being discharged again to the outside of the display device 100.

Although not illustrated, a cover glass may be bonded onto the polarizing layer 160 by a bonding layer. The bonding layer may serve to bond the constituent elements of the display device 100. For example, the bonding layer may be formed by using a bonding agent for an optically transparent display such as a pressure-sensitive bonding agent, an optically transparent bonding agent (optical clear adhesive (OCR)), or an optically transparent resin (optical clear resin (OCR)). However, the present disclosure is not limited thereto.

The cover glass may protect the constituent elements of the display device 100 from external impact and suppress damage such as scratches.

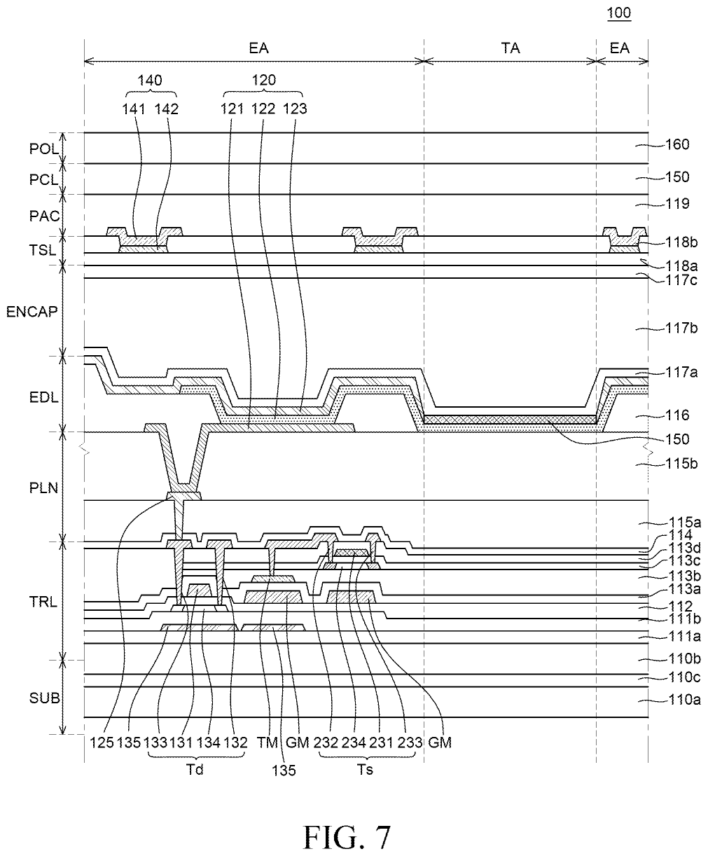

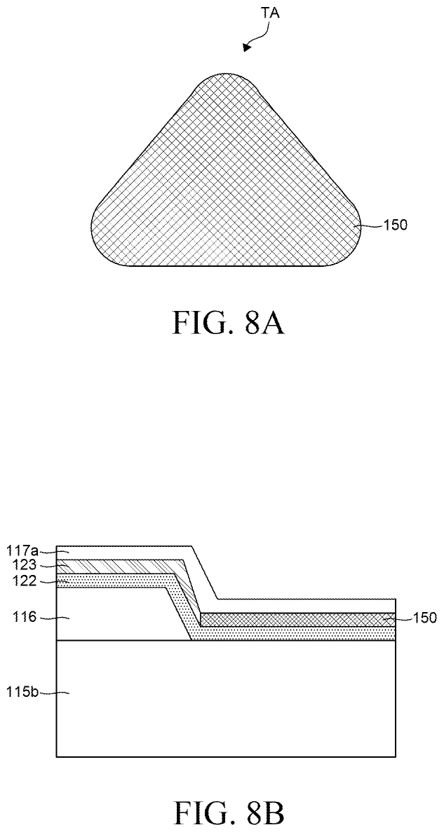

Hereinafter, the first optical area DA1 of the display device 100 will be described in more detail with reference to FIGS. 7 and 8.

FIG. 7 is a cross-sectional view illustrating cross-sectional structures of the light-emitting area and the transmissive area in the optical area according to the exemplary embodiment of the present specification. FIG. 8A is a view illustrating a positional relationship between the transmissive area and a deposition-suppressing layer according to the exemplary embodiment of the present specification. FIG. 8B is an enlarged view of the transmissive area according to the exemplary embodiment of the present specification.

Hereinafter, for convenience of description, an example will be described in which the display area DA of the display panel DP includes the general area NA and the first optical area DA1 (FIGS. 1A and 1B). However, the description of the first optical area DA1 may also be equally applied to the second optical area DA2.

With reference to FIG. 7, the first optical area DA1 includes the light-emitting area EA and a transmissive area TA.

Both a light-emitting area BA and the transmissive area TA of the first optical area DA1 may basically include the substrate SUB, the transistor layer TRL, the planarization layer PLN, the light-emitting element layer EDL, the sealing layer ENCAP, the touch sensor layer TSL, the protective layer PAC, the organic material layer PCL, and the polarizing layer POL.

The substrate SUB, the transistor layer TRL, the planarization layer PLN, the light-emitting element layer EDL, the sealing layer ENCAP, the touch sensor layer TSL, the protective layer PAC, the organic material layer PCL, and the polarizing layer POL, which are included in the first optical area DA1, are substantially identical to the constituent elements disposed in the general area NA of the display panel DP and denoted by the same reference numerals. Therefore, a repeated description will be omitted.

Because the light-emitting area EA of the first optical area DA1 is substantially identical in structure to the general area NA of the display panel DP, a repeated description thereof will be omitted.

Hereinafter, the transmissive area TA disposed in the first optical area DA1 will be described.

The substrate SUB and various types of insulation films 111a, 111b, 112, 113a, 113b, 114, 115a, 115b, 117a, 117b, 117c, and PAC disposed in the light-emitting area EA of the first optical area DA1 may also be disposed in the transmissive area TA of the first optical area DA1 in the same manner.

However, other than the insulating material disposed in the light-emitting area EA of the first optical area DA1, a material layer having electrical or opaque properties may not be disposed in the transmissive area TA of the first optical area DA1.

According to the exemplary embodiment of the present specification, the cathode 123 is not disposed in the transmissive area TA in order to ensure the transmittance of the transmissive area TA.

To implement this configuration, a deposition-suppressing layer 150 is disposed on the light-emitting layer 122 in the transmissive area TA.

For example, the deposition-suppressing layer 150 may be deposited while corresponding to the transmissive area TA by using a fine metal mask (FMM). Specifically, the FMM may be positioned to expose the transmissive area TA, and then the deposition-suppressing layer 150 may be formed.

In case that the cathode 123 is deposited after the deposition-suppressing layer 150 is disposed on the light-emitting layer 122 in the transmissive area TA, the cathode 123 may not be deposited in an area, in which the deposition-suppressing layer 150 is disposed, because a bonding force between the deposition-suppressing layer 150 and the layer disposed on the upper portion of the deposition-suppressing layer 150 is low.

Therefore, the cathode 123 may not be disposed in the transmissive area TA according to the exemplary embodiment of the present specification.

In addition, the semiconductor layer 134 and the metallic material layers 135, 131. GM, TM, 132, 133, and 125 related to the transistor are not disposed in the transmissive area TA. In addition, the anode 121 included in the light-emitting element 120 may also not be disposed in the transmissive area TA. In addition, the touch line may not be disposed in the transmissive area TA.

That is, because the transmissive area TA of the first optical area overlaps the optical-electronic device 170, the opaque constituent elements, such as the metal electrode, are not disposed in the transmissive area TA for a normal operation of the optical-electronic device 170, which may improve the transmittance of the transmissive area TA.

In addition, because the constituent element, such as the metal electrode, is not disposed in the transmissive area TA of the first optical area DA1, the transmissive area TA of the first optical area DA1 may be configured only by flat layers.

Meanwhile, the UV reliability may deteriorate when the cathode is removed to ensure the transmittance of the transmissive area TA in a UDC model or a UDIR model. That is, a pixel shrinkage defect of the light-emitting part may occur because of outgassing of an organic material caused by the transmission of UV rays.

Therefore, according to the exemplary embodiment of the present specification, it is possible to suppress the occurrence of outgassing of an organic material, which is caused by the transmission of UV rays, by reducing a volume of the organic material by removing a part of the organic material in the transmissive area TA.

According to the exemplary embodiment of the present specification, a bottom surface of the light-emitting layer 122 in the transmissive area TA of the first optical area DA1 may adjoin the planarization layer PLN. That is, the bank 116 may not be disposed in the transmissive area TA. Therefore, it is possible to reduce a volume of the organic material disposed in the transmissive area TA.

For example, in case that the volume of the organic material such as the bank is reduced in the transmissive area, the deposition-suppressing layer, which is subsequently disposed in the transmissive area, may be disposed not only on the upper portion of the light-emitting layer but also on the side surface of the bank. Because a bonding force between the deposition-suppressing layer and the layer disposed on the upper or lower portion of the deposition-suppressing layer is low, the separation of the film may occur because of a level difference in case that the level difference is present on the lower portion of the deposition-suppressing layer.

Therefore, according to the exemplary embodiment of the present specification, the deposition-suppressing layer 150 may be disposed on a flat surface in the optical area DA1. That is, according to the exemplary embodiment of the present specification, the lower portion of the deposition-suppressing layer 150 in the optical area DA1 may be flat, and the deposition-suppressing layer 150 may not overlap the bank 116.

According to the exemplary embodiment of the present specification, no level difference is present on the lower portion of the deposition-suppressing layer 150, which may suppress the separation of the film caused by the arrangement of the deposition-suppressing layer 150.

Meanwhile, because the deposition-suppressing layer 150 is disposed, the cathode 123 is not disposed on the upper portion of the deposition-suppressing layer 150 during a subsequent process of depositing the cathode 123. That is, the cathode 123 may be disposed only in the light-emitting area EA of the optical area DA1. The side surface of the cathode 123 disposed in the light-emitting area EA may adjoin the side surface of the deposition-suppressing layer 150 disposed in the transmissive area TA of the optical area DA1. However, the present disclosure is not limited thereto.

Meanwhile, with reference to FIGS. 8A and 8B together, an area of the transmissive area TA and an area of the deposition-suppressing layer 150 may be equal to each other. In this case, the deposition-suppressing layer 150 may have a constant thickness.

That is, because the deposition-suppressing layer 150 is disposed in the entire transmissive area TA, the opaque electrode, such as the cathode 123, is not disposed in the transmissive area TA, which may improve the transmittance.

FIG. 8A illustrates a structure in which the transmissive area TA has a triangular shape. However, the shape of the transmissive area TA according to the exemplary embodiment of the present specification is not limited thereto. For example, the transmissive area TA may have various shapes such as a circular shape, an elliptical shape, a quadrangular shape, a hexagonal shape, or an octagonal shape.

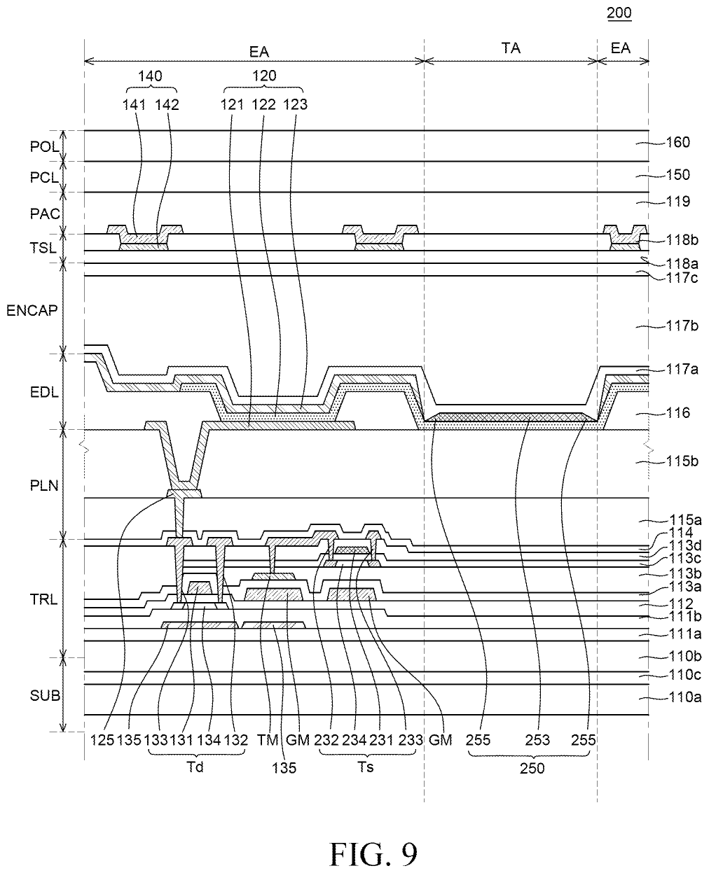

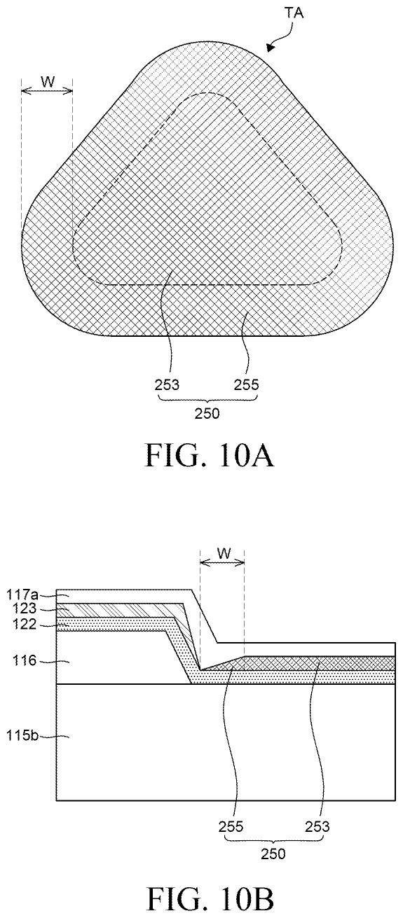

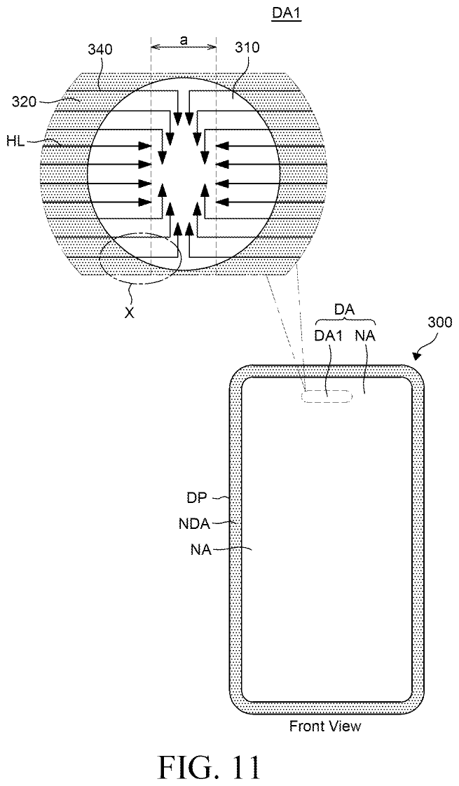

Hereinafter, a display device according to another exemplary embodiment of the present disclosure will be described with reference to FIGS. 9 and 10.

FIG. 9 is a cross-sectional view illustrating cross-sectional structures of the light-emitting area EA and the transmissive area TA in the optical area DA1 of a display device 200 according to another exemplary embodiment of the present specification. FIG. 10A is a view illustrating a positional relationship between the transmissive area TA and a deposition-suppressing layer 250 according to another exemplary embodiment of the present specification. FIG. 10B is an enlarged view of the transmissive area TA according to another exemplary embodiment of the present specification.

The display device in FIG. 9 is substantially identical in configuration to the display device in FIGS. 1 to 8, except for the deposition-suppressing layer 250. Therefore, for convenience of description, a repeated description will be omitted.

With reference to FIGS. 9 and 10, the deposition-suppressing layer 250 according to the exemplary embodiment of the present specification may include a first part 253 having a constant thickness, and a second part 255 disposed to surround the first part and having a smaller thickness than the first part.

In this case, the first part 253 and the second part 255 may be integrated and made of the same material.

For example, a thickness of the second part 255 may decrease as the distance from the first part 253 increases.

Specifically, according to another exemplary embodiment of the present specification, the deposition-suppressing layer 250 is deposited by using the FMM during a process of forming the deposition-suppressing layer 250. In this case, in case that the deposition-suppressing layer 250 is formed in a state in which the FMM is disposed to overlap a part of the flat surface of the transmissive area TA in consideration of a process margin, an area exposed from the FMM is formed as the first part 253 having a constant thickness, and an area, which overlaps the FMM, is formed as the second part 255 having a thickness that decreases as the distance from the first part 253 increases by the process margin.

With reference to FIGS. 10A and 10B together, an area of the transmissive area TA may be equal to an area of the deposition-suppressing layer 250 configured by the first part 253 and the second part 255. In this case, a width w in FIG. 10A corresponds to a width w, in FIG. 10B, of the second part 255 having a thickness that decreases as the distance from the first part 253 increases.

Therefore, the thickness of the second part 255 decreases as the second part 255 becomes closer to the light-emitting area EA. Therefore, the deposition-suppressing layer 250 configured by the first part 253 and the second part 255 according to another exemplary embodiment of the present specification may be more easily disposed only on the flat surface of the optical area DA1 without being disposed on a portion having a level difference, i.e., the bank 116 disposed in the light-emitting area EA.

According to another exemplary embodiment of the present specification, it is possible to further improve the effect of suppressing a film separation defect caused by the arrangement of the deposition-suppressing layer 250.

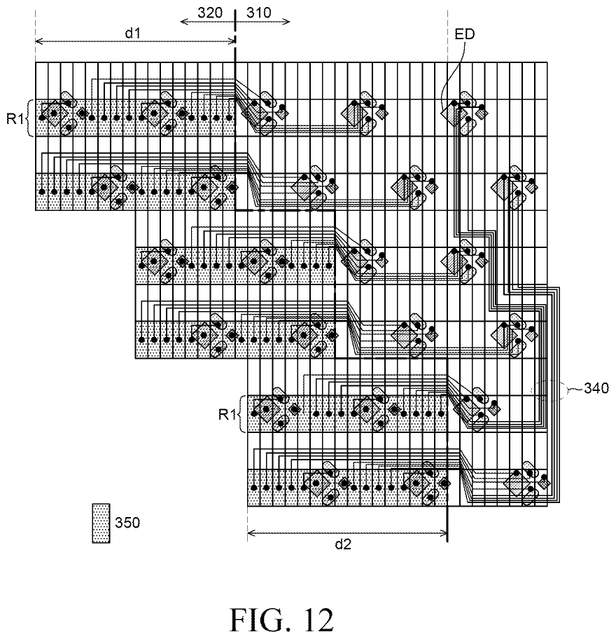

FIG. 11 is a top plan view illustrating the first optical area of the flexible display device according to another exemplary embodiment of the present specification. FIG. 12 is an enlarged view illustrating area X in FIG. 11.

First, with reference to FIG. 11, the first optical area DA1 may include a central area 310, and a bezel area 320 positioned at an outer periphery of the central area 310.

The first optical area DA1 may include a plurality of horizontal lines HL. The transistor positioned in the bezel area 320 and the light-emitting elements positioned in the central area 310 may be connected by the plurality of horizontal lines HL.

A flexible display device 300 according to the exemplary embodiment may include a routing structure 340. Because the flexible display device includes the routing structure 340, the central area 310 may be expanded by a predetermined area a. This is because the pixel positioned in the predetermined area a may be connected to the transistor positioned in the bezel area 320 by the routing structure 340.

A structure of the first optical area DA1 including the routing structure 340 will be specifically described below.

With reference to FIG. 12, the first optical area may include a plurality of light-emitting elements ED positioned in the central area 310 and the bezel area 320. The first optical area may include the plurality of light-emitting elements ED, such that the first optical area may display a screen.

The first optical area may include a plurality of transistors 350 positioned in the bezel area 320. The transistor 350 may not be positioned in the central area 310. Because the transistor is not positioned in the central area 310, the central area 310 may have higher transmittance.

The first optical area may include a plurality of rows including a first row R1 and a second row R2. The plurality of rows included in the first optical area may each be any area that traverses the first optical area in a horizontal direction. The plurality of rows may be defined by a pattern of the transistor 350.

The flexible display device may include the light-emitting elements ED positioned in the central area 310 and positioned in the first row R1, and the transistors 350 positioned in the bezel area 320 and positioned in the second row R2.

The flexible display device may include the routing structure 340 configured to connect the light-emitting elements ED positioned in the first row R1 and the transistor 350 positioned in the second row R2.

The transistors 350 and the light-emitting elements ED, which are positioned in different rows, may be connected by the routing structure 340. Therefore, it is possible to connect the transistors 350, which are positioned in the row in which the transistors 350 larger in number than the light-emitting elements ED are disposed, to the light-emitting elements ED positioned in the row in which the light-emitting elements ED larger in number than the transistors 350 are disposed.

The number of light-emitting elements ED included in the first row R1 in the central area 310 may be larger than the number of light-emitting elements ED included in the second row R2 in the bezel area 320. Therefore, a larger number of transistors 350 is required to operate the light-emitting elements ED included in the first row R1, and a smaller number of transistors 350 is required to operate the light-emitting elements ED included in the second row R2. Therefore, a surplus transistor 350, which is not electrically connected to the light-emitting element ED positioned in the second row R2 among the transistors 350 positioned in the second row R2 in the bezel area 320, may be electrically connected to the light-emitting element ED positioned in the first row R1 by the routing structure 340.

In the entire central area 310, the number of pixels per unit area may be substantially constant in the central area 310. For example, the configuration in which the number of pixels per unit area is substantially constant may mean that one pixel pattern is substantially uniform in the entire central area 310. Therefore, a large number of light-emitting elements ED may be positioned in the first row R1 in which an area, which overlaps the central area 310, is larger than that of the second row R2.

For example, the number of transistors 350 included in the first row R1 in the bezel area 320 may be substantially equal to the number of transistors 350 included in the second row R2 in the bezel area 320. In the example, when the number of light-emitting elements ED included in the first row R1 in the central area 310 is larger and the number of light-emitting elements ED included in the second row R2 in the central area 310 is smaller, some of the transistors 350 included in the second row R2 may be electrically connected to the light-emitting element ED positioned in the first row R1 without being electrically connected to the light-emitting element ED positioned in the second row R2.

Further, in the entire bezel area 320, the number of transistors 350 per unit area may be substantially constant in the bezel area 320. The configuration in which the number of transistors 350 per unit area is substantially constant may mean that one transistor pattern is substantially uniform in the bezel area 320.

An area of a region in which the bezel area 320 overlaps the first row R1 may be substantially equal to an area of a region in which the bezel area 320 overlaps the second row R2. In the example, the number of transistors 350 positioned in the first row R1 in the bezel area 320 may be substantially equal to the number of transistors 350 positioned in the second row R2 in the bezel area.

In case that the bezel area 320 is configured as described above, the number of transistors 350 positioned in the rows in the bezel area 320 may be constantly maintained, a surplus transistor in a particular row may be electrically connected to a surplus light-emitting element in another row by the routing structure 340. Therefore, the flexible display device according to the exemplary embodiment may have the central area 310 larger than that of a flexible display device of a comparative example.

The exemplary embodiments of the present disclosure can also be described as follows:

According to an aspect of the present disclosure, a display device comprises: a substrate comprising a non-display area and a display area which includes an optical area including a light-emitting area and a transmissive area, and a general area configured to surround the optical area, a planarization layer disposed on the substrate in the display area, a plurality of light-emitting elements disposed on the planarization layer and including an anode, a light-emitting layer, and a cathode, a bank disposed on the planarization layer and configured to cover an end of the anode, and a deposition-suppressing layer disposed on the light-emitting layer in the transmissive area among the light-emitting area and the transmissive area of the optical area, the bank is disposed in the light-emitting area among the light-emitting area and the transmissive area of the optical area.

The display device may further comprise an optical-electronic device disposed on a lower portion of the substrate in the optical area.

The deposition-suppressing layer may be disposed on a flat surface in the transmissive area of the optical area.

A bottom surface of the light-emitting layer may adjoin the planarization layer in the transmissive area of the optical area.

The deposition-suppressing layer and the bank may do not overlap each other in the optical area.

A side surface of the cathode disposed in the light-emitting area of the optical area may adjoin a side surface of the deposition-suppressing layer disposed in the transmissive area of the optical area.

The deposition-suppressing layer may have a constant thickness.

The deposition-suppressing layer may comprise a first part having a constant thickness, and a second part disposed to surround the first part and having a smaller thickness than the first part.

The thickness of the second part may decrease as the distance from the first part increases.

The first part and the second part may be integrated and made of the same material.

According to another aspect of the present disclosure, a display device comprises: a substrate comprising a non-display area and a display area which includes an optical area including a light-emitting area and a transmissive area, and a general area positioned to surround or be adjacent to the optical area; a planarization layer disposed on the substrate in the display area; a plurality of light-emitting elements disposed on the planarization layer and including an anode, a light-emitting layer and a cathode; a deposition-suppressing layer disposed on the light-emitting layer in the transmissive area, wherein the deposition-suppressing layer does not overlap the cathode; and an optical-electronic device disposed on a lower portion of the substrate in the optical area, wherein the optical-electronic device overlaps the deposition-suppressing layer.

The display device may further comprise a bank disposed on the planarization layer and configured to cover an end of the anode, wherein the bank is disposed in the light-emitting area.

The deposition-suppressing layer may be disposed on a flat surface in the transmissive area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope of the embodiments described herein should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device comprising:
a substrate comprising a non-display area and a display area, the display area including an optical area including a light-emitting area and a transmissive area, and a general area that is adjacent to the optical area;
a planarization layer disposed on the substrate in the display area;
a plurality of light-emitting elements disposed on the planarization layer, each including an anode, a light-emitting layer, and a cathode;
a bank disposed on the planarization layer and covering an end of the anode; and
a deposition-suppressing layer disposed on the light-emitting layer in the transmissive area between the light-emitting area and the transmissive area of the optical area,
wherein the bank is disposed in the light-emitting area and between the light-emitting area and the transmissive area of the optical area.

2. The display device of claim 1, further comprising:
an optical-electronic device disposed on a lower portion of the substrate in the optical area.

3. The display device of claim 1, wherein the deposition-suppressing layer is disposed on a flat surface in the transmissive area of the optical area.

4. The display device of claim 1, wherein a bottom surface of the light-emitting layer adjoins the planarization layer in the transmissive area of the optical area.

5. The display device of claim 1, wherein the deposition-suppressing layer and the bank do not overlap each other in the optical area.

6. The display device of claim 1, wherein a side surface of the cathode disposed in the light-emitting area of the optical area adjoins a side surface of the deposition-suppressing layer disposed in the transmissive area of the optical area.

7. The display device of claim 1, wherein at least a part of the deposition-suppressing layer has a constant thickness.

8. The display device of claim 7, wherein the deposition-suppressing layer comprises:
a first part having the constant thickness; and
a second part that surrounds the first part, the second part having a smaller thickness than the first part.

9. The display device of claim 8, wherein the thickness of the second part decreases as a distance from the first part increases.

10. The display device of claim 8, wherein the first part and the second part are integral to each other and made of a same material.

11. A display device comprising:
a substrate comprising a non-display area and a display area, the display area including an optical area including a light-emitting area and a transmissive area, and a general area that is adjacent to the optical area;
a planarization layer disposed on the substrate in the display area;
a plurality of light-emitting elements disposed on the planarization layer, each including an anode, a light-emitting layer and a cathode;
a deposition-suppressing layer disposed on the light-emitting layer in the transmissive area, wherein the deposition-suppressing layer does not overlap the cathode; and
an optical-electronic device disposed on a lower portion of the substrate in the optical area, wherein the optical-electronic device overlaps the deposition-suppressing layer.

12. The display device of claim 11, further comprising:
a bank disposed on the planarization layer and covering an end of the anode, wherein the bank is disposed in the light-emitting area.

13. The display device of claim 11, wherein the deposition-suppressing layer is disposed on a flat surface in the transmissive area.
